(19) United States
(12) Patent Application Publication
(10) Pub. No.: US 2026/0242542 A1
(43) Pub. Date: Aug. 20, 2026

(54) SUBSTITUTED POLYPHENYLENE SULFIDE RESIN

(71) Applicants: Daicel Corporation, Osaka-shi, Osaka (JP); Waseda University, Tokyo (JP)

(72) Inventors: Shinsuke ISHIKAWA, Tokyo (JP); Keizo INOUE, Tokyo (JP); Daisuke ITO, Tokyo (JP); Kenichi OYAIZU, Tokyo (JP)

(73) Assignees: Daicel Corporation, Osaka-shi, Osaka (JP); Waseda University, Tokyo (JP)

(21) Appl. No.: 18/995,039

(22) PCT Filed: Dec. 8, 2023
(86) PCT No.: PCT/JP2023/043937

§ 371 Date: Jan. 15, 2025

(30) Foreign Application Priority Data
Dec. 15, 2022 (JP) 2022-199863
Aug. 31, 2023 (JP) 2023-140600

(51) Int. Cl. C08G 75/0227; C08G 75/029; C08J 5/24; C09D 181/02

(52) U.S. Cl. CPC C08G 75/0227; C08G 75/029; C08J 5/24; C09D 181/02; C08J 2381/02

(57) ABSTRACT

Provided is a substituted polyphenylene sulfide resin containing a constituent unit represented by General formula (1):

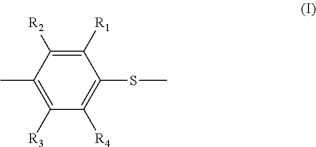

wherein R₁, R₂, R₃, and R₄ are each independently H, an alkyl group, an alkoxy group, or an alkenyl group-containing organic group, and one or more of R₁, R₂, R₃, and R₄ are an alkyl group or an alkoxy group.

### TECHNICAL FIELD

The present disclosure relates to a substituted polyphenylene sulfide resin.

### BACKGROUND ART

In recent years, high-speed and large-capacity mobile communication systems have been developed. With the progress of such mobile communication systems, higher frequency bands have been used for communication. For example, in a fifth generation mobile communication system which has already started to be put into practical use, a frequency band higher than that of a fourth generation or earlier mobile communication system is used.

In a terminal of a mobile communication system, attenuation of an electric signal through a circuit of a printed wiring board, so-called a transmission loss, occurs. The transmission loss depends also on dielectric characteristics of a board (dielectric) of the printed wiring board. In general, a higher frequency used has a greater influence on dielectric loss tangent and causes a greater transmission loss.

Suppression of a transmission loss in a printed wiring board used for communication in a high frequency band is required for enabling higher-speed mobile communication. Therefore, a low transmission loss is also required of a resin or resin composition serving as a material for a printed wiring board. A resin or resin composition having a low dielectric loss tangent is required for ensuring a low transmission loss.

Resin compositions containing a polyphenylene ether (PPE) resin (for example, Patent Document 1) or a polyphenylene sulfide (PPS) resin (for example, Patent Documents 2 and 3) as a main component have been widely used as materials for wiring boards such as printed wiring boards. However, the PPE resin itself has low flame retardancy, and thus there is a problem that it is necessary to impart flame retardancy to the resin composition by mixing it with a flame retardant material to use it as a material for a wiring board. In addition, an unsubstituted PPS resin has a high dielectric loss tangent, and therefore has a problem that the transmission loss also increases in communication applications in a high frequency band.
Patent Document 1: JP 2005-60635 A
Patent Document 2: JP 2002-225029 A
Patent Document 3: JP H5-98157 A

### SUMMARY OF INVENTION

An object of the present disclosure is to provide a resin having a low dielectric loss tangent.

As a result of intensive studies to solve the above problems, the present inventors have found that a substituted polyphenylene sulfide (also referred to as substituted PPS) resin containing a constituent unit represented by a predetermined formula has a low dielectric loss tangent.

Accordingly, the present disclosure includes the following aspects.

### [1] First Aspect

[1-1]A substituted polyphenylene sulfide resin for a wiring board, the substituted polyphenylene sulfide resin containing a constituent unit represented by General formula (I):

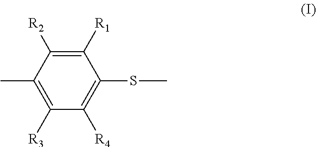

[wherein R₁, R₂, R₃, and R₄ are each independently H, an alkyl group, an alkoxy group, or an alkenyl group-containing organic group, and one or more of R₁, R₂, R₃, and R₄ are an alkyl group or an alkoxy group].
[1-2] The substituted polyphenylene sulfide resin for a wiring board according to [1-1], wherein the substituted polyphenylene sulfide resin has a dielectric loss tangent at 10 GHz of less than 0.002.
[1-3] The substituted polyphenylene sulfide resin for a wiring board according to [1-1] or [1-2], wherein the substituted polyphenylene sulfide resin contains a constituent unit represented by General formula (II):

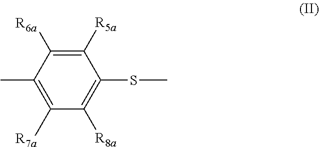

[wherein R₅ₐ, R₆ₐ, R₇ₐ, and R₈ₐ are each independently H, an alkyl group, an alkoxy group, or an alkenyl group-containing organic group, and one or more of R₅ₐ, R₆ₐ, R₇ₐ, and R₈ₐ are an alkenyl group-containing organic group]; and/or a terminal structure represented by General formula (III-a):

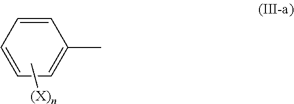

[wherein Xs are each independently H, an alkyl group, an alkoxy group, or an alkenyl group-containing organic group, one or more of Xs are an alkenyl group-containing organic group, and n is an integer of from 1 to 5].
[1-4] The substituted polyphenylene sulfide resin for a wiring board according to [1-3], wherein the terminal structure represented by General formula (III-a) is a terminal structure represented by General formula (III-b):

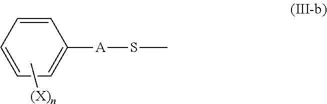

[wherein Xs are each independently H, an alkyl group, an alkoxy group, or an alkenyl group-containing organic group, one or more of Xs are an alkenyl group-containing organic group, n is an integer of from 1 to 5, and A is represented by General formula (IV):

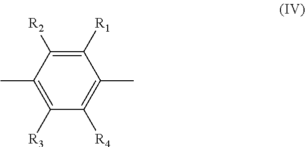

{wherein R₁, R₂, R₃, and R₄ are each independently H, an alkyl group, an alkoxy group, or an alkenyl group-containing organic group, and one or more of R₁, R₂, R₃, and R₄ are an alkyl group or an alkoxy group}].
[1-5] The substituted polyphenylene sulfide resin for a wiring board according to [1-3], wherein the terminal structure represented by General formula (III-a) is a terminal structure represented by General formula (III):

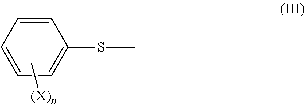

[wherein Xs are each independently H, an alkyl group, an alkoxy group, or an alkenyl group-containing organic group, one or more of Xs are an alkenyl group-containing organic group, and n is an integer of from 1 to 5].
[1-6] The substituted polyphenylene sulfide resin for a wiring board according to any of [1-1] to [1-5], wherein the substituted polyphenylene sulfide resin has a glass transition temperature of 250° C. or lower.
[1-7] The substituted polyphenylene sulfide resin for a wiring board according to any of [1-1] to [1-6], wherein a content of the constituent unit containing an alkyl group and/or an alkoxy group is 30 mol % or more.
[1-8] The substituted polyphenylene sulfide resin for a wiring board according to any of [1-1] to [1-7], wherein a content of the constituent unit containing an alkenyl group-containing organic group is 20 mol % or less.
[1-9]A resin composition containing the substituted polyphenylene sulfide resin for a wiring board described in any of [1-1] to [1-8].
[1-10]A varnish containing the resin described in any of [1-1] to [1-8] or the resin composition described in [1-9] and a solvent.
[1-11] An interlayer insulating material containing the resin described in any of [1-1] to [1-8] or the resin composition described in [1-9].
[1-12]A prepreg containing the resin described in any of [1-1] to [1-8] or the resin composition described in [1-9] and a base material.
[1-13]A metal-clad laminate containing the resin described in any of [1-1] to [1-8] or the resin composition described in [1-9] and a metal foil.
[1-14]A substrate containing the resin described in any of [1-1] to [1-8] or the resin composition described in [1-9].
[1-15]A wiring board containing the resin described in any of [1-1] to [1-8] or the resin composition described in [1-9].
[1-16]A printed wiring board containing the wiring board described in [1-15] and an electronic component.
[1-17] The printed wiring board according to [1-16], wherein the printed wiring board has a dielectric loss tangent at 10 GHz of less than 0.002.

### [2] Second Aspect

[2-1]A substituted polyphenylene sulfide resin containing a constituent unit represented by General formula (I):

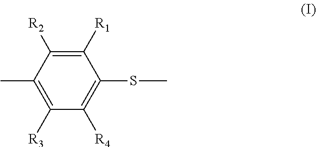

[wherein R₁, R₂, R₃, and R₄ are each independently H, an alkyl group, an alkoxy group, or an alkenyl group-containing organic group, and one or more of R₁, R₂, R₃, and R₄ are an alkyl group or an alkoxy group], wherein
the substituted polyphenylene sulfide resin has a dielectric loss tangent at 10 GHz of less than 0.002.
[2-2] The substituted polyphenylene sulfide resin according to [2-1], wherein the substituted polyphenylene sulfide resin contains a constituent unit represented by General formula (II):

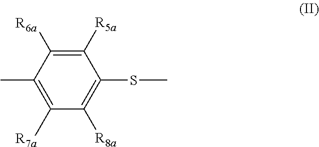

[wherein R₅ₐ, R₆ₐ, R₇ₐ, and R₈ₐ are each independently H, an alkyl group, an alkoxy group, or an alkenyl group-containing organic group, and one or more of R₅ₐ, R₆ₐ, R₇ₐ, and R₈ₐ are an alkenyl group]; and/or a terminal structure represented by General formula (III-a):

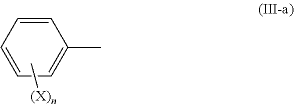

[wherein Xs are each independently H, an alkyl group, an alkoxy group, or an alkenyl group-containing organic group, one or more of Xs are an alkenyl group-containing organic group, and n is an integer of from 1 to 5].
[2-3] The substituted polyphenylene sulfide resin according to [2-2], wherein the terminal structure represented by General formula (III-a) is a terminal structure represented by General formula (III-b):

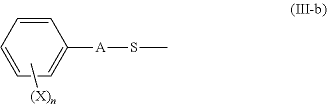

[wherein Xs are each independently H, an alkyl group, an alkoxy group, or an alkenyl group-containing organic group, one or more of Xs are an alkenyl group-containing organic group, n is an integer of from 1 to 5, and A is represented by General formula (IV):

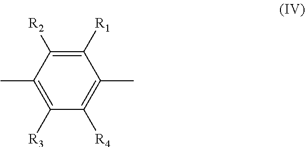

{wherein R₁, R₂, R₃, and R₄ are each independently H, an alkyl group, an alkoxy group, or an alkenyl group-containing organic group, and one or more of R₁, R₂, R₃, and R₄ are an alkyl group or an alkoxy group}].
[2-4] The substituted polyphenylene sulfide resin according to [2-2], wherein the terminal structure represented by General formula (III-a) is a terminal structure represented by General formula (III):

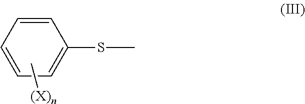

[wherein Xs are each independently H, an alkyl group, an alkoxy group, or an alkenyl group-containing organic group, one or more of Xs are an alkenyl group-containing organic group, and n is an integer of from 1 to 5].
[2-5] The substituted polyphenylene sulfide resin according to any of [2-1] to [2-4], wherein the substituted polyphenylene sulfide resin has a glass transition temperature of 250° C. or lower.
[2-6] The substituted polyphenylene sulfide resin according to any of [2-1] to [2-5], wherein a content of the constituent unit containing an alkyl group and/or an alkoxy group is 30 mol % or more.
[2-7] The substituted polyphenylene sulfide resin according to any of [2-1] to [2-6], wherein a content of the constituent unit containing an alkenyl group-containing organic group is 20 mol % or less.
[2-8]A resin composition containing the substituted polyphenylene sulfide resin described in any of [2-1] to [2-7].
[2-9]A varnish containing the resin described in any of [2-1] to [2-7] or the resin composition described in [2-8] and a solvent.
[2-10] An interlayer insulating material containing the resin described in any of [2-1] to [2-7] or the resin composition described in [2-8].
[2-11]A prepreg containing the resin described in any of [2-1] to [2-7] or the resin composition described in [2-8] and a base material.
[2-12]A metal-clad laminate containing the resin described in any of [2-1] to [2-7] or the resin composition described in [2-8] and a metal foil.
[2-13]A substrate containing the resin described in any of [2-1] to [2-7] or the resin composition described in [2-8].
[2-14]A wiring board containing the resin described in any of [2-1] to [2-7] or the resin composition described in [2-8].
[2-15]A printed wiring board containing the wiring board described in [2-14] and an electronic component.
[2-16] The printed wiring board according to [2-15], wherein the printed wiring board has a dielectric loss tangent at 10 GHz of less than 0.002.

### [3] Third Aspect

[3-1]A substituted polyphenylene sulfide resin having a terminal structure represented by General formula (III-a):

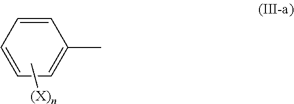

[wherein Xs are each independently H, an alkyl group, an alkoxy group, or an alkenyl group-containing organic group, one or more of Xs are an alkenyl group-containing organic group, and n is an integer of from 1 to 5].
[3-2] The substituted polyphenylene sulfide resin according to [3-1], wherein the terminal structure represented by General formula (III-a) is a terminal structure represented by General formula (III-b):

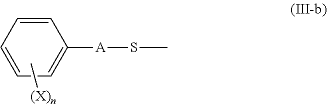

[wherein Xs are each independently H, an alkyl group, an alkoxy group, or an alkenyl group-containing organic group, one or more of Xs are an alkenyl group-containing organic group, n is an integer of from 1 to 5, and A is represented by General formula (IV):

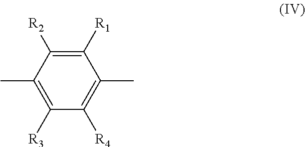

{wherein R₁, R₂, R₃, and R₄ are each independently H, an alkyl group, an alkoxy group, or an alkenyl group-containing organic group, and one or more of R₁, R₂, R₃, and R₄ are an alkyl group or an alkoxy group}].
[3-3] The substituted polyphenylene sulfide resin according to [3-1], wherein the terminal structure represented by General formula (III-a) is a terminal structure represented by General formula (III):

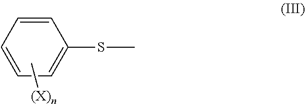

[wherein Xs are each independently H, an alkyl group, an alkoxy group, or an alkenyl group-containing organic group, one or more of Xs are an alkenyl group-containing organic group, and n is an integer of from 1 to 5].
[3-4] The substituted polyphenylene sulfide resin according to any of [3-1] to [3-3], wherein the substituted polyphenylene sulfide resin contains a constituent unit represented by General formula (I):

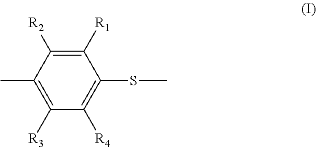

[wherein R₁, R₂, R₃, and R₄ are each independently H, an alkyl group, an alkoxy group, or an alkenyl group-containing organic group, and one or more of R₁, R₂, R₃, and R₄ are an alkyl group or an alkoxy group].
[3-5] The substituted polyphenylene sulfide resin according to [3-1] or [3-2], wherein the substituted polyphenylene sulfide resin has a dielectric loss tangent at 10 GHz of less than 0.002.
[3-6] The substituted polyphenylene sulfide resin according to any of [3-1] to [3-5], wherein the substituted polyphenylene sulfide resin contains a constituent unit represented by General formula (II):

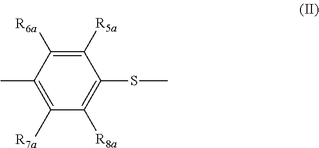

[wherein R₅ₐ, R₆ₐ, R₇ₐ, and R₈ₐ are each independently H, an alkyl group, an alkoxy group, or an alkenyl group-containing organic group, and one or more of R₅ₐ, R₆ₐ, R₇ₐ, and R₈ₐ are an alkenyl group-containing organic group].
[3-7] The substituted polyphenylene sulfide resin according to any of [3-1] to [3-6], wherein the substituted polyphenylene sulfide resin has a glass transition temperature of 250° C. or lower.
[3-8] The substituted polyphenylene sulfide resin according to any of [3-1] to [3-7], wherein a content of the constituent unit containing an alkyl group and/or an alkoxy group is 30 mol % or more.
[3-9] The substituted polyphenylene sulfide resin according to any of [3-1] to [3-8], wherein a content of the constituent unit containing an alkenyl group-containing organic group is 20 mol % or less.
[3-10]A resin composition containing the substituted polyphenylene sulfide resin described in any of [3-1] to [3-9].
[3-11]A varnish containing the resin described in any of [3-1] to [3-9] or the resin composition described in [3-6] and a solvent.
[3-12] An interlayer insulating material containing the resin described in any of [3-1] to [3-9] or the resin composition described in [3-6].
[3-13]A prepreg containing the resin described in any of [3-1] to [3-9] or the resin composition described in [3-6] and a base material.
[3-14]A metal-clad laminate containing the resin described in any of [3-1] to [3-9] or the resin composition described in [3-6] and a metal foil.
[3-15]A substrate containing the resin described in any of [3-1] to [3-9] or the resin composition described in [3-6].
[3-16]A wiring board containing the resin described in any of [3-1] to [3-9] or the resin composition described in [3-6].
[3-17]A printed wiring board containing the wiring board described in [3-16] and an electronic component.
[3-18] The printed wiring board according to [3-17], wherein the printed wiring board has a dielectric loss tangent at 10 GHz of less than 0.002.

The first aspect and the second aspect of the present disclosure can provide a resin having a low dielectric loss tangent.

The third aspect of the present disclosure can provide a novel substituted PPS resin.

### BRIEF DESCRIPTION OF DRAWINGS

FIG. 1 illustrates a synthesis scheme of a vinyl-substituted PPS resin (terminal).

FIG. 2 is a graph (a) illustrating an upfield shift of a signal of a terminal aromatic proton by NMR analysis and a graph (b) illustrating the presence of a terminal vinyl group, for substituted PPSs of Examples 15 to 18.

### DESCRIPTION OF EMBODIMENTS

Hereinafter, embodiments of the present disclosure will be described in detail. The present disclosure is not limited to the following embodiments, and can be carried out with appropriate changes as long as the effects of the present disclosure are not impaired.

Each of the configurations, combinations thereof, and the like in each of the embodiments are an example, and various additions, omissions, substitutions, and other changes of the configurations may be made as appropriate without departing from the spirit of the present disclosure. The present disclosure is not limited by the embodiments and is limited only by the claims.

Each aspect disclosed in the present specification can be combined with any other feature disclosed herein.

When a particular description given for an embodiment also applies to another embodiment, the description may be omitted in the other embodiment.

In the present disclosure, the expression “from X to Y” with regard to a numerical range means “X or more and Y or less”.

### First Embodiment (Substituted PPS Resin for Wiring Board)

[Substituted PPS resin for Wiring Board]

A resin according to a first embodiment is a substituted PPS resin for a wiring board, the resin containing a constituent unit represented by General formula (I).

General formula (I):

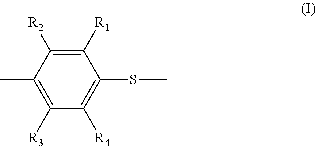

[wherein R₁, R₂, R₃, and R₄ are each independently H, an alkyl group, an alkoxy group, or an alkenyl group-containing organic group, and one or more of R₁, R₂, R₃, and R₄ are an alkyl group or an alkoxy group].

### (For Wiring Board)

In the present specification, the “wiring board” “for a wiring board” includes all portions other than an electronic component such as a semiconductor chip in a printed wiring board (also referred to as printed circuit board). In general, the printed wiring board has a structure in which a semiconductor package including an electronic component such as a semiconductor chip mounted on a pedestal called substrate is mounted on a print circuit board (PCB), but the “board” “for a wiring board” also includes a substrate.

Therefore, the phrase “for a wiring board” means that the substituted PPS resin is used as a material for a wiring board, which is used to be attached with an electronic component such as a semiconductor chip and to be provided with wiring.

The substituted PPS resin for a wiring board according to the present embodiment contains the constituent unit represented by General formula (I), and thus is suitably used as a material for a wiring board because of its property of having a low dielectric loss tangent.

In one embodiment, the substituted PPS resin for a wiring board may be composed only of the substituted PPS resin which will be described below, or may contain any other resin.

For example, the substituted PPS resin for a wiring board according to the present embodiment may contain one or more of resins such as a substituted PPS resin other than the substituted PPS resin described in the present embodiment, an unsubstituted PPS resin, and/or a resin other than a PPS resin.

### (Substituted PPS Resin Containing Constituent Unit Having Alkyl Group or Alkoxy Group)

A substituted PPS resin according to the first embodiment contains a constituent unit represented by General formula (I).

General formula (I):

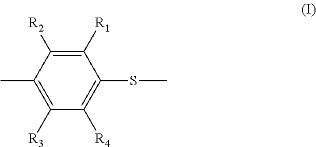

[wherein R₁, R₂, R₃, and R₄ are each independently H, an alkyl group, an alkoxy group, or an alkenyl group-containing organic group, and one or more of R₁, R₂, R₃, and R₄ are an alkyl group or an alkoxy group].

Here, the alkyl group may be a linear, branched, or cyclic alkyl group, and is preferably a linear, branched, or cyclic alkyl group having from 1 to 10 carbons. Examples of the linear, branched, or cyclic alkyl group having from 1 to 10 carbons include a methyl group, an ethyl group, an n-propyl group, an isopropyl group, an n-butyl group, a tert-butyl group, an s-isobutyl group, an n-pentyl group, an isopentyl group, a neopentyl group, an n-hexyl group, an isohexyl group, an n-heptyl group, an n-octyl group, an isooctyl group, an n-nonyl group, an isononyl group, an n-decyl group, an isodecyl group, a cyclopropyl group, a cyclobutyl group, a cyclopentyl group, a cyclohexyl group, a cycloheptyl group, and a cyclooctyl group.

In one embodiment, the alkyl group is preferably a methyl group, an ethyl group, and/or an isopropyl group.

The alkoxy group may be a linear, branched, or cyclic alkoxy group, and is preferably a linear, branched, or cyclic alkoxy group having from 1 to 10 carbons. Examples of the linear or branched alkoxy group having from 1 to 10 carbons include a methoxy group, an ethoxy group, an n-propoxy group, an isopropoxy group, an n-butoxy group, a tert-butoxy group, an s-butoxy group, an isobutoxy group, an n-pentyloxy group, an isopentyloxy group, a neopentyloxy group, an n-hexyloxy group, an isohexyloxy group, an s-hexyloxy group, a tert-hexyloxy group, a neohexyloxy group, an n-heptyloxy group, an n-octyloxy group, an isooctyloxy group, an n-nonyloxy group, an isononyloxy group, an n-decyloxy group, an isodecyloxy group, a cyclopropoxy group, a cyclobutoxy group, a cyclopentyloxy group, a cyclohexyloxy group, a cycloheptyloxy group, a cyclooctyloxy group, a cyclononyloxy group, and a cyclodecyloxy group.

In one embodiment, the alkoxy group is preferably a methoxy group.

In one embodiment, the alkyl group is preferably linear or branched in consideration of ease of synthesis of the substituted PPS resin. The number of carbons of the alkyl group is preferably from 1 to 6, more preferably from 1 to 5, and even more preferably from 1 to 4. In one embodiment, the alkyl group may be an alkyl group having 4 carbons, an alkyl group having 3 carbons, an alkyl group having 2 carbons, or an alkyl group having 1 carbon.

In one embodiment, the alkoxy group is preferably linear or branched in consideration of ease of synthesis of the substituted PPS resin. The number of carbons of the alkoxy group is preferably from 1 to 6, more preferably from 1 to 5, and even more preferably from 1 to 4. In one embodiment, the alkoxy group may be an alkoxy group having 4 carbons, an alkoxy group having 3 carbons, an alkoxy group having 2 carbons, or an alkoxy group having 1 carbon.

In consideration of ease of synthesis of the substituted PPS resin, the alkyl group or the alkoxy group is preferably an alkyl group, more preferably a linear alkyl group, even more preferably a linear alkyl group having from 1 to 4 carbons, still even more preferably an ethyl group or a methyl group, and still even more preferably a methyl group.

The position of substitution with the alkyl group or the alkoxy group in General formula (I) is not limited, and may be one or more of R₁, R₂, R₃, and R₄.

When one alkyl group or alkoxy group is contained in General formula (I), the substitution position thereof may be any of R₁, R₂, R₃, and R₄. The substitution position may be R₁, R₂, R₃, or R₄.

When a total of two or more alkyl groups and/or alkoxy groups are contained in General formula (I), a combination of the substitution positions thereof is not limited. For example, when two alkyl groups and/or alkoxy groups are contained, the substitution positions may be any combination of R₁ and R₂, R₁ and R₃, R₁ and R₄, R₂ and R₃, R₂ and R₄, and R₃ and R₄. In one embodiment, the substitution positions of the alkyl group and/or the alkoxy group may be any two of R₁, R₂, and R₃. When the substitution positions are any two of R₁, R₂ and R₃, the substitution positions may be any combination of R₁ and R₃ or R₂ and R₃.

When a total of three alkyl groups and/or alkoxy groups are contained in General formula (I), the substitution positions may be any combination of R₁, R₂, and R₃, R₁, R₂, and R₄, R₁, R₃, and R₄, or R₂, R₃, and R₄.

In one embodiment, in the substituted PPS resin, one or more of R₁, R₂, R₃, and R₄ in the constituent unit represented by General formula (I) may be an aryl group having from 1 to 10 carbons. Examples of the aryl group having from 1 to 10 carbons include a phenyl group and a naphthyl group.

When one or more alkyl groups, alkoxy groups, and/or aryl groups are contained in General formula (I), the dielectric loss tangent of the substituted PPS resin containing the constituent unit represented by General formula (I) tends to be low. As a result, the dielectric loss tangent of the resin composition containing the substituted PPS resin tends to be low.

The constituent unit represented by General formula (I) also includes a case where one or more of R₁, R₂, R₃ and R₄ are an alkyl group or an alkoxy group, and one or more of R₁, R₂, R₃ and R₄ which are neither an alkyl group nor an alkoxy group are an alkenyl group-containing organic group.

In the substituted PPS resin, R₁, R₂, R₃, and R₄ which are neither an alkyl group nor an alkoxy group in formula (I) may each independently be an alkenyl group-containing organic group.

Here, the alkenyl group-containing organic group is not limited as long as it contains one or more alkenyl groups in the substituent, and may be an alkenylene group in which a COO group (ester) or a CO group (ketone) is interposed. The alkenyl group-containing organic group may be a linear, branched, or cyclic alkenyl group, and is preferably a linear, branched, or cyclic alkenyl group having from 2 to 10 carbons. Examples of the linear, branched, or cyclic alkenyl group having from 2 to 10 carbons include a substituent containing one or more carbon-carbon double bonds in the chain of an alkyl group having 2 or more carbons, and specific examples thereof include a vinyl group, an allyl group, a 1-propenyl group, an isopropenyl group, a 3-butenyl group, a 2-butenyl group, a 1-butenyl group, a 1,3-butadienyl group, a 4-pentenyl group, a 3-pentenyl group, a 2-pentenyl group, a 1-pentenyl group, a 1,3-pentadienyl group, a 2,4-pentadienyl group, a 1,1-dimethyl-2-propenyl group, a 1-ethyl-2-propenyl group, a 1,2-dimethyl-1-propenyl group, a 1-methyl-1-butenyl group, a 5-hexenyl group, a 4-hexenyl group, a 2-hexenyl group, a 1-hexenyl group, a 1-methyl-1-hexenyl group, a 2-methyl-2-hexenyl group, a 3-methyl-1,3-hexadienyl group, a 1-heptenyl group, a 2-octenyl group, a 3-nonenyl group, a 4-decenyl group, a cyclopropenyl group, a cyclobutenyl group, a cyclopentenyl group, a cyclohexenyl group, a cycloheptenyl group, a cyclooctenyl group, a cyclononenyl group, a cyclodecenyl group, an acrylic group (acryloyl group), a methacrylic group (methacryloyl group), an acryloyloxyalkyl group, and a methacryloyloxyalkyl group.

In one embodiment, the alkenyl group-containing organic group is preferably a vinyl group, an allyl group, and/or an acrylic group.

In one embodiment, the alkenyl group-containing organic group is preferably linear or branched in consideration of ease of synthesis of the substituted PPS resin. The number of carbons of the alkenyl group-containing organic group is preferably from 2 to 6, more preferably from 2 to 5, even more preferably from 2 to 4, and still even more preferably from 2 to 3. In one embodiment, the alkenyl group-containing organic group may be an acrylic group or an alkenyl group having 3 carbons, or an alkenyl group having 2 carbons.

In one embodiment, when one or more of R₁, R₂, R₃, and R₄ in the constituent unit represented by General formula (I) are an alkenyl group-containing organic group, even if the substituted PPS resin is composed only of the constituent unit represented by General formula (I) or includes one or more constituent units other than the constituent unit represented by General formula (I), the substituted PPS resin tends to exhibit thermosetting property and/or good reflow resistance. As a result, the resin composition containing the substituted PPS resin easily exhibits thermosetting property and/or good reflow resistance.

Meanwhile, the unsubstituted PPS resin has good flame retardancy. Therefore, the substituted PPS resin containing the constituent unit represented by General formula (I) and having the same basic skeleton as that of the unsubstituted PPS has good flame retardancy. The same applies to other constituent units having a PPS skeleton whose basic skeleton is the same as that of the unsubstituted PPS, and the substituted PPS resin containing the constituent unit represented by General formula (II) or the terminal structure represented by General formula (III), which will be described below, also has good flame retardancy.

As a result, the resin composition containing the substituted PPS resin has good flame retardancy.

### (Substituted PPS Resin Containing Constituent Unit Having Alkenyl Group-Containing Organic Group)

In one embodiment, the substituted PPS resin according to the first embodiment may contain a constituent unit represented by General formula (II):

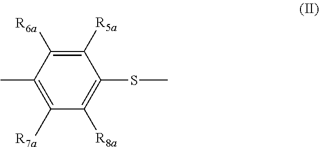

[wherein R₅ₐ, R₆ₐ, R₇ₐ, and R₈ₐ are each independently H, an alkyl group, an alkoxy group, or an alkenyl group-containing organic group, and one or more of R₅ₐ, R₆ₐ, R₇ₐ, and R₈ₐ are an alkenyl group-containing organic group]; and/or a terminal structure represented by
   General formula (III-a):

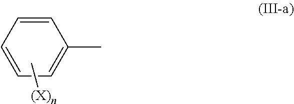

[wherein Xs are each independently H, an alkyl group, an alkoxy group, or an alkenyl group-containing organic group, one or more of Xs are an alkenyl group-containing organic group, and n is an integer of from 1 to 5].

The terminal structure represented by General formula (III-a) may be a terminal structure represented by General formula (III-b):

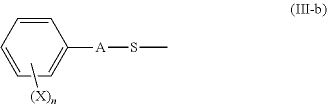

[wherein Xs are each independently H, an alkyl group, an alkoxy group, or an alkenyl group-containing organic group, one or more of Xs are an alkenyl group-containing organic group, n is an integer of from 1 to 5, and A is represented by General formula (IV):

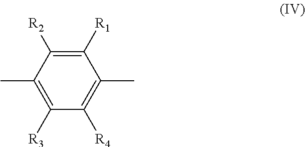

{wherein R₁, R₂, R₃, and R₄ are each independently H, an alkyl group, 20 an alkoxy group, or an alkenyl group-containing organic group, and one or more of R₁, R₂, R₃, and R₄ are an alkyl group or an alkoxy group}].

The terminal structure represented by General formula (Ill-a) may be a terminal structure represented by General formula (III):

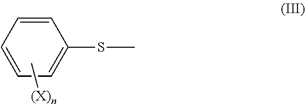

[wherein Xs are each independently H, an alkyl group, an alkoxy group, or an alkenyl group-containing organic group, one or more of Xs are an alkenyl group-containing organic group, and n is an integer of from 1 to 5].

The constituent unit represented by General formula (II) represents that one or more of substituents are an alkenyl group-containing organic group in constituent units other than the constituent unit located at the terminal of the resin among the constituent units contained in the substituted PPS resin.

The constituent units represented by General formulae (III-a), (III-b), and (III) represent that one or more of substituents are an alkenyl group-containing organic group in the constituent units located at one or both terminals of the resin among the constituent units contained in the substituted PPS resin.

Examples and preferred examples of the alkyl group, alkoxy group, and alkenyl group-containing organic group in General formula (II) and General formulae (III-a), (III-b), and (III) include the alkyl group, alkoxy group, and alkenyl group-containing organic group exemplified in the description of General formula (I). The number of carbons of the alkyl group or the alkoxy group may also be the number of carbons exemplified in the description of General formula (I).

The number of carbons of the alkenyl group-containing organic group in General formula (II) and General formulae (III-a), (III-b), and (III) is preferably from 2 to 6, more preferably from 2 to 5, even more preferably from 2 to 4, and still even more preferably from 2 to 3 in consideration of ease of synthesis of the substituted PPS resin. In one embodiment, the alkenyl group-containing organic group may be an alkenyl group-containing organic group having 3 carbons or an alkenyl group-containing organic group having 2 carbons, and may be, for example, an allyl group or an acrylic group having 3 carbons and/or a vinyl group having 2 carbons.

Here, the position of substitution with the alkenyl group-containing organic group in General formula (II) is not limited, and may be one or more of R₅ₐ, R₆ₐ, R₇ₐ, and R₈ₐ.

When one alkenyl group-containing organic group is contained in General formula (II), the substitution position thereof may be any of R₅ₐ, R₆ₐ, R₇ₐ, and R₈ₐ. The substitution position may be R₅ₐ, R₆ₐ, R₇ₐ, or R₈ₐ.

When two or more alkenyl group-containing organic groups are contained in General formula (II), a combination of the substitution positions thereof is not limited. For example, when two alkenyl group-containing organic groups are contained, the substitution positions may be any combination of R₈ₐ and R₆ₐ, R₈ₐ and R₇ₐ, R₈ₐ and R₈ₐ, R₆ₐ and R₇ₐ, R₆ₐ and R₈ₐ, or R₇ₐ and R₈ₐ. In one embodiment, the substitution position of the alkenyl group-containing organic group may be any two of R₈ₐ, R₆ₐ, and R₇ₐ, or any combination of R₈ₐ and R₇ₐ, or R₆ₐ and R₇ₐ.

For example, when three alkenyl group-containing organic groups are contained in General formula (II), the substitution positions may be any combination of R₈ₐ, R₆ₐ, and R₇ₐ, R₅ₐ, R₆ₐ, and R₈ₐ, R₅ₐ, R₇ₐ, and R₈ₐ, or R₆ₐ, R₇ₐ, and R₈.

General formula (II) also includes a case where one or more of R₈ₐ, R₆ₐ, R₇ₐ, and R₈ₐ are an alkenyl group-containing organic group, and one or more of R₅ₐ, R₆ₐ, R₇ₐ, and R₈ₐ which are not an alkenyl group-containing organic group are an alkyl group or an alkoxy group. Further, General formulae (III-a), (III-b), and (III) also include a case where one or more of Xs are an alkenyl group, and one or more of Xs which are not an alkenyl group-containing organic group are an alkyl group or an alkoxy group. The position of substitution with the alkyl group or alkoxy group in General formula (II) may be any of R₈ₐ, R₆ₐ, R₇ₐ, and R₈ₐ, and examples thereof and preferred examples thereof include the substitution positions exemplified in the description of General formula (I).

The position of substitution with the alkyl group or alkoxy group in General formulae (III-a), (III-b), and (III) is not limited, and may be any of the five Xs.

Here, the position of substitution with the alkenyl group-containing organic group in General formula (III-a), (III-b), or (III) is not limited, and may be one or more of the five Xs. When one alkenyl group-containing organic group is contained in General formula (III-a), (III-b), or (III), the substitution position thereof may be an ortho position, a meta position, or a para position with respect to S.

When a total of two or more alkenyl group-containing organic groups are contained in General formula (III-a), (III-b), or (III), a combination of the substitution positions thereof is not limited. For example, when two alkenyl group-containing organic groups are contained, the substitution positions may be 2,3-position (or 5,6-position), 2,4-position (or 4,6-position), 2,5-position (or 3,6-position), 2,6-position, 3,4-position (or 4,5-position), or 3,5-position.

For example, when three alkenyl group-containing organic groups are contained in General formula (III-a), (III-b), or (III), the substitution positions may be 2,3,4-position (or 4,5,6-position), 2,3,5-position (or 3,5,6-position), 2,3,6-position (or 2,5,6-position), 2,4,5-position (or 3,4,6-position), 2,4,6-position, or 3,4,5-position.

When one or more alkenyl group-containing organic groups are contained in General formula (II) and General formula (III-a), General formula (III-b), or General formula (III), the substituted PPS resin containing the constituent unit represented by General formula (II) and/or the terminal structure represented by General formula (III-a), (III-b), or (III) easily exhibits thermosetting property and/or good reflow resistance. As a result, the resin composition containing the substituted PPS resin easily exhibits thermosetting property and/or good reflow resistance. The substituted PPS resin preferably contains the terminal structure represented by General formula (III-a), (III-b), or (III) at at least either one of its terminals, and more preferably contains the terminal structure represented by General formula (III-a), (III-b), or (III) at both of its terminals, from the viewpoint of easily exhibiting thermosetting property and good reflow resistance. Even when the substituted PPS resin does not have the terminal structure represented by General formula (III-a), (III-b), or (III) at either of its terminals, a resin containing one or more alkenyl group-containing organic groups in General formula (II) can be used in combination with an additive well known to those skilled in the art for improving its curability, such as a crosslinking agent, whereby the resin composition containing the substituted PPS resin can be provided with desired thermosetting property and/or desired reflow resistance as a material for a wiring board.

### (Polymer Structure)

The substituted PPS resin has a polymer structure including two or more constituent units (monomer units) capable of constituting the resin. The substituted PPS resin according to the first embodiment contains a constituent unit represented by General formula (I) as at least a part of constituent units of the resin, and may contain one or more constituent units represented by a general formula other than General formula (I).

Here, the constituent unit represented by General formula (I) may be one constituent unit, or may be two or more constituent units as long as they are represented by General formula (I). The constituent unit represented by General formula (I) includes two or more constituent units having different combinations of substituents in R₁, R₂, R₃, and R₄ as exemplified in the description of General formula (I).

Here, the one or more constituent units represented by a general formula other than General formula (I) include, but are not limited to, an unsubstituted PPS (PPS in which all substituents in General formula (I) are H) unit, a constituent unit represented by General formula (II), and a terminal structure represented by General formula (III-a), (III-b), or (III).

The constituent unit represented by General formula (II) may be one constituent unit, or may be two or more constituent units as long as they are represented by General formula (II). The constituent unit represented by General formula (II) includes two or more constituent units having different combinations of substituents in R₅ₐ, R₆ₐ, R₇ₐ, and R₈ₐ as exemplified in the description of General formula (II).

The terminal structure represented by General formula (Ill-a), (III-b), or (III) may be one type of terminal structure, that is, both terminals of the resin have the same general formula and have the same substituents, or may be two types of terminal structures as long as they are represented by General formula (Ill-a), (III-b), or (III), that is, the respective terminals of the resin may have different structures. The terminal structures represented by General formulae (Ill-a), (III-b), and (III) include two or more terminal structures having different combinations of substituents in five Xs as exemplified in the descriptions of General formulae (Ill-a), (III-b), and (III). From the viewpoint of easily exhibiting thermosetting property and/or easily improving reflow resistance, the terminal structure may be one type of terminal structure or two types of terminal structures. However, in consideration of ease of synthesis of the substituted PPS resin, preferably, both terminals of the resin have one type of terminal structure, that is, the terminals have the same general formula and have the same substituent.

In the substituted PPS resin, the order of bonding of the constituent units is not limited. For example, the constituent units represented by General formula (I) having the same combination of substituents may be adjacent to each other; the constituent units represented by General formula (II) having the same combination of substituents may be adjacent to each other; the constituent units represented by General formula (I) having different combinations of substituents may be adjacent to each other; the constituent units represented by General formula (II) having different combinations of substituents may be adjacent to each other; the constituent unit represented by General formula (I) may be adjacent to the constituent unit represented by General formula (II); or the constituent unit represented by General formula (I) or (II) may be adjacent to a constituent unit other than the constituent unit represented by General formula (I) or (II). Further, the terminal structure represented by General formula (III-a), (III-b), or (III) may be bonded to both or one of the terminals of the plurality of constituent units bonded in any order.

In one embodiment, the substituted PPS resin may contain a constituent unit represented by General formula (I) wherein R₂ and R₃ are an alkyl group having from 1 to 5 carbons, and R₁ and R₄ are H, may contain a constituent unit represented by General formula (I) wherein R₁ and R₃ are an alkyl group having from 1 to 5 carbons, and R₂ and R₄ are H, may contain a constituent unit represented by General formula (I) wherein R₂ is an alkyl group having from 1 to 5 carbons, and R₁, R₃, and R₄ are H, may contain a constituent unit represented by General formula (I) wherein R₁ is an alkyl group having from 1 to 5 carbons, and R₂, R₃, and R₄ are H, may contain a constituent unit represented by General formula (I) wherein R₂ and R₃ are an alkoxy group having from 1 to 5 carbons, and R₁ and R₄ are H, may contain a constituent unit represented by General formula (I) wherein R₂ and R₃ are a methyl group, and R₁ and R₄ are H, may contain a constituent unit represented by General formula (I) wherein R₁ and R₃ are a methyl group, and R₂ and R₄ are H, may contain a constituent unit represented by General formula (I) wherein R₂ is a methyl group, and R₁, R₃, and R₄ are H, may contain a constituent unit represented by General formula (I) wherein R₁ is an isopropyl group, and R₂, R₃, and R₄ are H, or may contain a constituent unit represented by General formula (I) wherein R₂ and R₃ are a methoxy group, and R₁ and R₄ are H.

In one embodiment, the substituted PPS resin may contain a constituent unit represented by General formula (I) or General formula (II) wherein R₂ or R₃ (in General formula (II), R₆ₐ or R₇ₐ) is an alkyl group having from 1 to 5 carbons, and R₂ or R₃ (in General formula (II), R₆ₐ or R₇ₐ) which is not an alkyl group is an alkenyl group-containing organic group having 2 or 3 carbons, and R₁ and R₄ (in General formula (II), R₅ₐ or R₈ₐ) are H, may contain a constituent unit represented by General formula (III-a), (III-b), or (III) wherein the group at at least one of 2-position, 3-position, 4-position, and 5-position is an alkenyl group-containing organic group having 2 or 3 carbons, and Xs which are not an alkenyl group-containing organic group are each H or an alkyl group having from 1 to 5 carbons, and a constituent unit represented by General formula (I) wherein R₂ and R₃ are an alkyl group having from 1 to 5 carbons, and R₁ and R₄ are H, may contain a constituent unit represented by General formula (I) or General formula (II) wherein R₂ or R₃ (in General formula (II), R₆ₐ or R₇ₐ) is a methyl group, and R₂ or R₃ (in General formula (II), R₆ₐ or R₇ₐ) which is not a methyl group is a vinyl group, R₁ and R₄ (in General formula (II), R₅ₐ or R₈ₐ) are H, or may contain a constituent unit represented by General formula (III-a), (III-b), or (III) wherein the group at at least one of 2-position, 3-position, 4-position, and 5-position is a vinyl group, and Xs which are not a vinyl group are each H or a methyl group, and a constituent unit represented by General formula (I) wherein R₂ or R₃ is a methyl group, and R₁ and R₄ are H.

In one embodiment, the substituted PPS resin may contain a constituent unit represented by General formula (I) or General formula (II) wherein R₂ or R₃ (in General formula (II), R₆ₐ or R₇ₐ) is an alkyl group having from 1 to 5 carbons, and R₂ or R₃ (in General formula (II), R₆ₐ or R₇ₐ) which is not an alkyl group is an alkenyl group-containing organic group having 2 or 3 carbons, and R₁ and R₄ (in General formula (II), R₅ₐ or R₈ₐ) are H, may contain a constituent unit represented by General formula (III-a), (III-b), or (III) wherein the group at at least either one of 3-position and 5-position is an alkenyl group-containing organic group having 2 or 3 carbons, and Xs which are not an alkenyl group-containing organic group are each H or an alkyl group having from 1 to 5 carbons, and a constituent unit represented by General formula (I) wherein R₂ and R₃ are an alkyl group having from 1 to 5 carbons, and R₁ and R₄ are H, may contain a constituent unit represented by General formula (I) or General formula (II) wherein R₂ or R₃ (in General formula (II), R₆ₐ or R₇ₐ) is a methyl group, and R₂ or R₃ (in General formula (II), R₆ₐ or R₇ₐ) which is not a methyl group is a vinyl group, R₁ and R₄ (in General formula (II), R₅ₐ or R₈ₐ) are H, or may contain a constituent unit represented by General formula (III-a), (III-b), or (III) wherein the group at at least either one of 3-position and 5-position is a vinyl group, and Xs which are not a vinyl group are each H or a methyl group, and a constituent unit represented by General formula (I) wherein R₂ or R₃ is a methyl group, and R₁ and R₄ are H.

In one embodiment, the substituted PPS resin may have an alkenyl group-containing organic group at any substitution position in General formula (I), General formula (II), and/or General formula (III-a), (III-b), or (III), and the alkenyl group-containing organic group may have 2 or 3 carbons, or may be a vinyl group.

In one embodiment, the substituted PPS resin may be one or more selected from a 3,5-dimethyl PPS resin, a 2,5-dimethyl PPS resin, a 3-monomethyl PPS resin, and a 2-isopropyl PPS resin, which may have one or more alkenyl group-containing organic groups having 2 or 3 carbons. In one embodiment, the substituted PPS resin may be one or more selected from a 3,5-dimethyl PPS resin, a 2,5-dimethyl PPS resin, a 3-monomethyl PPS resin, and a 2-isopropyl PPS resin, which may have one or more vinyl groups.

The content of the constituent unit represented by General formula (I) or the contents of the constituent unit represented by General formula (I) and the constituent unit represented by General formula (II) in the substituted PPS resin are not limited as long as the substituted PPS resin and/or the resin composition containing the substituted PPS resin has a desired dielectric loss tangent. The content of the constituent unit containing an alkyl group and/or an alkoxy group in the substituted PPS resin is preferably 30 mol % or more. When the content is 30 mol % or more, it may be 40 mol % or more, 50 mol % or more, 60 mol % or more, 70 mol % or more, 80 mol % or more, 90 mol % or more, or 100 mol %.

When the content of the constituent unit containing an alkyl group and/or an alkoxy group in the substituted PPS resin is 30 mol % or more, the dielectric loss tangent of the substituted PPS resin is likely to be in a desired range, and as a result, the dielectric loss tangent of the resin composition containing the substituted PPS resin is likely to be in a desired range.

In one embodiment, the content of the constituent unit having an alkenyl group-containing organic group in the substituted PPS resin is not limited as long as the substituted PPS resin and/or the resin composition containing the substituted PPS resin exhibits desired thermosetting property, but the upper limit of the content is 20 mol % or less, preferably 18 mol % or less, more preferably from 1 to 18 mol %, even more preferably from 2 to 10 mol %, and still even more preferably from 2 to 7% mol %. When the content is 18 mol % or less, it may be 15 mol % or less, 10 mol % or less, 7 mol % or less, 5 mol % or less, 4 mol % or less, 3 mol % or less, or 1 mol or less. As the lower limit, the content of the constituent unit having an alkenyl group-containing organic group in the substituted PPS resin is preferably at least 1 constituent unit or more. Here, when the content of the constituent unit having an alkenyl group-containing organic group in the substituted PPS resin is 1 constituent unit, one of the terminal structures of the substituted PPS resin may have an alkenyl group-containing organic group, or 1 constituent unit other than the terminal structures may have an alkenyl group-containing organic group. Even when only 1 constituent unit of the substituted PPS resin has an alkenyl group-containing organic group, the substituted PPS resin is likely to exhibit thermosetting property and/or good reflow resistance.

When the lower limit of the content of the constituent unit having an alkenyl group-containing organic group in the substituted PPS resin is 1 constituent unit or more, the lower limit may be 2 constituent units or more, 0.1 mol % or more, 0.2 mol % or more, 0.5 mol % or more, or 0.8 mol % or more.

In one embodiment, the content of the constituent unit having an alkenyl group-containing organic group in the substituted PPS resin may be in a range obtained by combining any of the upper limits and any of the lower limits described above.

For example, the content of the constituent unit having an alkenyl group-containing organic group in the substituted PPS resin may be 1 constituent unit or more and 18 mol % or less, 1 constituent unit or more and 15 mol % or less, 1 constituent unit or more and 10 mol % or less, 1 constituent unit or more and 7 mol % or less, 1 constituent unit or more and 5 mol % or less, 1 constituent unit or more and 4 mol % or less, 1 constituent unit or more and 3 mol % or less, or 1 constituent unit or more and 1 mol % or less. The content may be 2 constituent units or more and 18 mol % or less, 2 constituent units or more and 15 mol % or less, 2 constituent units or more and 10 mol % or less, 2 constituent units or more and 7 mol % or less, 2 constituent units or more and 5 mol % or less, 2 constituent units or more and 4 mol % or less, 2 constituent units or more and 3 mol % or less, or 2 constituent units or more and 1 mol % or less. The content may be 0.1 mol % or more and 18 mol % or less, 0.1 mol % or more and 15 mol % or less, 0.1 mol % or more and 10 mol % or less, 0.1 mol % or more and 7 mol % or less, 0.1 mol % or more and 5 mol % or less, 0.1 mol % or more and 4 mol % or less, 0.1 mol % or more and 3 mol % or less, or 0.1 mol % or more and 1 mol % or less. The content may be 0.2 mol % or more and 18 mol % or less, 0.2 mol % or more and 15 mol % or less, 0.2 mol % or more and 10 mol % or less, 0.2 mol % or more and 7 mol % or less, 0.2 mol % or more and 5 mol % or less, 0.2 mol % or more and 4 mol % or less, 0.2 mol % or more and 3 mol % or less, or 0.2 mol % or more and 1 mol % or less. The content may be 0.5 mol % or more and 18 mol % or less, 0.5 mol % or more and 15 mol % or less, 0.5 mol % or more and 10 mol % or less, 0.5 mol % or more and 7 mol % or less, 0.5 mol % or more and 5 mol % or less, 0.5 mol % or more and 4 mol % or less, 0.5 mol % or more and 3 mol % or less, or 0.5 mol % or more and 1 mol % or less.

The content may be 0.8 mol % or more and 18 mol % or less, 0.8 mol % or more and 15 mol % or less, 0.8 mol % or more and 10 mol % or less, 0.8 mol % or more and 7 mol % or less, 0.8 mol % or more and 5 mol % or less, 0.8 mol % or more and 4 mol % or less, 0.8 mol % or more and 3 mol % or less, or 0.8 mol % or more and 1 mol % or less.

When the content of the constituent unit having an alkenyl group-containing organic group in the substituted PPS resin is 1 constituent unit or more and 20 mol % or less, the substituted PPS resin easily exhibits thermosetting property and/or good reflow resistance. As a result, the resin composition containing the substituted PPS resin easily exhibits thermosetting property and/or good reflow resistance.

When the content of the constituent unit having an alkenyl group-containing organic group in the substituted PPS resin is 1 constituent unit or more and 20 mol % or less, the dielectric loss tangent at 10 GHz of the substituted PPS resin is likely to be less than 0.002, and the dielectric loss tangent at 40 GHz is likely to be less than 0.003. Furthermore, when the content of the constituent unit having an alkenyl group-containing organic group in the substituted PPS resin is 1 constituent unit or more and 20 mol % or less, the dielectric constant at 10 GHz is likely to be less than 3.00.

### (Dielectric Loss Tangent)

In one embodiment, the substituted PPS resin preferably has a dielectric loss tangent at 10 GHz of less than 0.002. As a result, the dielectric loss tangent at 10 GHz of the resin composition containing the substituted PPS resin is likely to be less than 0.002.

In one embodiment, the substituted PPS resin more preferably has a dielectric loss tangent at 10 GHz of less than 0.0015. As a result, the dielectric loss tangent at 10 GHz of the resin composition containing the substituted PPS resin is likely to be less than 0.0015.

In one embodiment, the substituted PPS resin more preferably has a dielectric loss tangent at 10 GHz of less than 0.001. As a result, the dielectric loss tangent at 10 GHz of the resin composition containing the substituted PPS resin is likely to be less than 0.001.

In one embodiment, when the dielectric loss tangent at 10 GHz of the substituted PPS resin is less than 0.001, the dielectric loss tangent may be less than 0.00095, less than 0.0009, less than 0.00085, or less than 0.0008.

In one embodiment, the substituted PPS resin preferably has a dielectric loss tangent at 40 GHz of less than 0.003. As a result, the dielectric loss tangent at 40 GHz of the resin composition containing the substituted PPS resin is likely to be less than 0.003.

In one embodiment, when the dielectric loss tangent at 40 GHz of the substituted PPS resin is less than 0.003, the dielectric loss tangent may be less than 0.0025, less than 0.002, less than 0.0015, or less than 0.0012.

In one embodiment, the substituted PPS resin preferably has a dielectric loss tangent at 80 GHz of less than 0.004. As a result, the dielectric loss tangent at 80 GHz of the resin composition containing the substituted PPS resin is likely to be less than 0.004.

In one embodiment, when the substituted PPS resin has a dielectric loss tangent at 80 GHz of less than 0.004, the dielectric loss tangent may be less than 0.003, less than 0.0025, or less than 0.002.

When the substituted PPS resin has a lower dielectric loss tangent, the transmission loss is more easily suppressed when the substituted PPS resin or the resin composition containing the substituted PPS resin is used as a material for a wiring board.

The dielectric loss tangent is adjusted by a method involving adjusting the content of the constituent unit represented by General formula (I), General formula (II), and/or General formula (III-a), (III-b), or (III) in the substituted PPS resin, a method involving adjusting the number of carbons of the alkyl group or alkoxy group in the constituent unit represented by General formula (I), General formula (II), and/or General formula (Ill-a), (III-b), or (III), a method involving adjusting the number of substituents in the constituent unit represented by General formula (I), General formula (II), and/or General formula (Ill-a), (III-b), or (III), or a method involving adjusting the substitution position in the constituent unit represented by General formula (I), General formula (II), and/or General formula (Ill-a), (III-b), or (III). By any of these methods or a combination thereof, the dielectric loss tangent can be adjusted to be lower, the dielectric loss tangent at 10 GHz can be adjusted to be less than 0.002, the dielectric loss tangent at 40 GHz can be adjusted to be less than 0.003, and the dielectric loss tangent at 80 GHz can be adjusted to be less than 0.004.

For example, the dielectric loss tangent can be adjusted to be lower by increasing the content of the constituent unit represented by General formula (I) in the substituted PPS resin. For example, when the substituted PPS resin contains the constituent unit represented by General formula (I) in an amount of 30 mol % or more, the dielectric loss tangent can be adjusted to be lower.

For example, the dielectric loss tangent can be adjusted to be lower by decreasing the number of carbons of the alkyl group or the alkoxy group in the constituent unit represented by General formula (I) in the substituted PPS resin.

For example, the dielectric loss tangent can be adjusted to be lower by decreasing the number of carbons of the alkyl group or the alkoxy group in the constituent unit represented by General formula (I) in the substituted PPS resin.

More specifically, for example, when the substituted PPS resin contains a constituent unit represented by General formula (I) substituted with an alkyl group having a small number of carbons (for example, from 1 to 5 carbons), the dielectric loss tangent can be adjusted to be lower than that in a case where the substituted PPS resin contains a constituent unit substituted with an alkyl group or alkoxy group having a relatively large number of carbons.

In one embodiment, the substituted PPS resin contains a constituent unit represented by General formula (I), and preferably has a dielectric loss tangent at 10 GHz of less than 0.002.

In one embodiment, the substituted PPS resin contains a constituent unit represented by General formula (II), and preferably has a dielectric loss tangent at 10 GHz of less than 0.002.

In one embodiment, the substituted PPS resin contains a terminal structure represented by General formula (III), and preferably has a dielectric loss tangent at 10 GHz of less than 0.002.

(Dielectric Constant) In one embodiment, the substituted PPS resin preferably has a dielectric constant at 10 GHz of less than 3.00. As a result, the dielectric constant at 10 GHz of the resin composition containing the substituted PPS resin is likely to be less than 3.00.

In one embodiment, the substituted PPS resin more preferably has a dielectric constant at 10 GHz of less than 2.80. As a result, the dielectric constant at 10 GHz of the resin composition containing the substituted PPS resin is likely to be less than 2.80.

In one embodiment, when the substituted PPS resin has a dielectric constant at 10 GHz of less than 2.80, the dielectric constant may be less than 2.75, less than 2.65, less than 2.60, less than 2.50, or less than 2.40.

When the substituted PPS resin has a lower dielectric constant, the transmission loss is more easily suppressed when the substituted PPS resin or the resin composition containing the substituted PPS resin is used as a material for a wiring board.

The dielectric constant is adjusted by a method involving adjusting the content of the constituent unit represented by General formula (I), General formula (II), and/or General formula (III-a), (III-b), or (III) in the substituted PPS resin, a method involving adjusting the number of carbons of the alkyl group or alkoxy group in the constituent unit represented by General formula (I), General formula (II), and/or General formula (Ill-a), (III-b), or (III), a method involving adjusting the number of substituents in the constituent unit represented by General formula (I), General formula (II), and/or General formula (Ill-a), (III-b), or (III), or a method involving adjusting the substitution position in the constituent unit represented by General formula (I), General formula (II), and/or General formula (Ill-a), (III-b), or (III). By any of these methods or a combination thereof, the dielectric constant can be adjusted to be lower, and the dielectric loss tangent at 10 GHz can be adjusted to be less than 3.00.

For example, the dielectric constant can be adjusted to be lower by increasing the content of the constituent unit represented by General formula (I) in the substituted PPS resin. For example, when the substituted PPS resin contains the constituent unit represented by General formula (I) in an amount of 30 mol % or more, the dielectric constant can be adjusted to be lower. More specifically, for example, when the substituted PPS resin contains the constituent unit in an amount of 40 mol % or more, the dielectric constant at 10 GHz can be adjusted to less than 3.00.

For example, the dielectric constant can be adjusted to be lower by decreasing the number of carbons of the alkyl group or the alkoxy group in the constituent unit represented by General formula (I) in the substituted PPS resin.

For example, the dielectric constant can be adjusted to be lower by decreasing the number of carbons of the alkyl group or the alkoxy group in the constituent unit represented by General formula (I) in the substituted PPS resin. More specifically, for example, when the substituted PPS resin contains a constituent unit represented by General formula (I) substituted with an alkyl group having a small number of carbons (for example, from 1 to 5 carbons), the dielectric constant can be adjusted to be lower than that in a case where the substituted PPS resin contains a constituent unit substituted with an alkyl group or alkoxy group having a relatively large number of carbons.

### (Measurement of Dielectric Loss Tangent and Dielectric Constant)

For measurement of the dielectric loss tangent and the dielectric constant, a film of a resin or a resin composition prepared to have a thickness of from 50 to 250 μm can be heated at from 200° C. to 250° C. for 120 minutes to form a sample piece of the resin or the resin composition for measurement, and the sample piece can be used.

The dielectric loss tangent and the dielectric constant can be measured at 10 GHz, 40 GHz, or 80 GHz under conditions of a standard environment (23±2° C.) and a relative humidity of from 45 to 55% by means of a vector network analyzer (N5290A) and a split cylinder resonator, both available from Keysight Technologies.

In one embodiment, the substituted PPS resin contains a constituent unit represented by General formula (I), and preferably has a dielectric loss tangent at 10 GHz of less than 0.002. Furthermore, the dielectric constant at 10 GHz may be less than 3.00.

In one embodiment, the substituted PPS resin contains constituent units represented by General formula (I) and General formula (II), and preferably has a dielectric loss tangent at 10 GHz of less than 0.002. Furthermore, the dielectric constant at 10 GHz may be less than 3.00.

In one embodiment, the substituted PPS resin contains the terminal structures represented by General formula (I) and General formula (III-a), (III-b), or (III), and preferably has a dielectric loss tangent at 10 GHz of less than 0.002. Furthermore, the dielectric constant at 10 GHz may be less than 3.00.

### (Glass Transition Temperature)

In one embodiment, the upper limit of the glass transition temperature (Tg) of the substituted PPS resin is preferably 250° C. or lower, more preferably 200° C. or lower, and even more preferably 170° C. or lower. The lower limit of the glass transition temperature is preferably 25° C. or higher. When the lower limit is 25° C. or higher, it may be 30° C., 40° C., 50° C., 60° C., 70° C., 80° C., 90° C., or 100° C.

In one embodiment, the glass transition temperature of the substituted PPS resin is preferably 250° C. or lower, and more preferably from 25° C. to 250° C. When the glass transition temperature is from 25° C. to 250° C., it may be in a range obtained by combining any of the upper limits and any of the lower limits described above. For example, the glass transition temperature of the substituted PPS resin may be from 25 to 200° C., from 25 to 170° C., from 30 to 250° C., from 30 to 200° C., from 30 to 170° C., from 40 to 250° C., from 40 to 200° C., from 40 to 170° C., from 50 to 250° C., from 50 to 200° C., from 50 to 170° C., from 60 to 250° C., from 60 to 200° C., from 60 to 170° C., from 70 to 250° C., from 70 to 200° C., from 70 to 170° C., from 80 to 250° C., from 80 to 200° C., from 80 to 170° C., from 90 to 250° C., from 90 to 200° C., from 90 to 170° C., from 100 to 250° C., from 100 to 200° C., or from 100 to 170° C.

When the glass transition temperature of the substituted PPS resin is 250° C. or lower, the glass transition temperature of the resin composition containing the substituted PPS resin is also likely to be 250° C. or lower.

The wiring board is molded by, for example, a molding method including a heating step and a curing step. Therefore, molding may become difficult depending on the difference between the glass transition temperature and the curing temperature of the material. When the glass transition temperature of the substituted PPS resin is 250° C. or lower, a wiring board can be easily molded by a molding method including a heating step and a curing step by using the substituted PPS resin or the resin composition containing the substituted PPS resin. If the glass transition temperature of the material is too low, the tackiness may increase, and the molding of the wiring board may become difficult. When the glass transition temperature of the substituted PPS resin is 25° C. or higher, the wiring board can be easily molded by a molding method including a heating step and a curing step. In addition, when the glass transition temperature of the substituted PPS resin is from 25 to 250° C., a product exemplified in “Product” in the present embodiment can be easily produced.

The glass transition temperature is adjusted by a method involving adjusting the content of the constituent unit represented by General formula (I), General formula (II), and/or General formula (III-a), (III-b), or (III) in the substituted PPS resin, a method involving adjusting the number of carbons of the alkyl group or alkoxy group in the constituent unit represented by General formula (I), General formula (II), and/or General formula (III-a), (III-b) or (III), a method involving adjusting the number of substituents in the constituent unit represented by General formula (I), General formula (II), and/or General formula (III), a method involving adjusting the substitution position in the constituent unit represented by General formula (I), General formula (II), and/or General formula (III-a), (III-b), or (III), or a method involving adjusting the weight average molecular weight of the substituted PPS resin. The glass transition temperature of the substituted PPS resin can be adjusted to 250° C. or lower by any of these methods or a combination thereof.

For example, when the weight average molecular weight of the substituted PPS resin is 33000 or less, the glass transition temperature can be easily adjusted to fall within a desired range. More specifically, when the weight average molecular weight is 33000 or less, the glass transition temperature can be adjusted to 250° C. or lower. When the weight average molecular weight is 33000 or less, it may be less than 21000.

The glass transition temperature can be measured by differential scanning calorimetry (DSC) in accordance with JIS standard (JIS K 7121: Method for measuring transition temperature of plastics) under a temperature increase condition at 20° C./min from room temperature.

In one embodiment, the substituted PPS resin contains a constituent unit represented by General formula (I), and preferably has a dielectric loss tangent at 10 GHz of less than 0.002 and a glass transition temperature of 250° C. or lower.

In one embodiment, the substituted PPS resin contains a constituent unit represented by General formula (II), and preferably has a dielectric loss tangent at 10 GHz of less than 0.002 and a glass transition temperature of 250° C. or lower.

In one embodiment, the substituted PPS resin contains a terminal structure represented by General formula (III-a), (III-b), or (III), and preferably has a dielectric loss tangent at 10 GHz of less than 0.002 and a glass transition temperature of 250° C. or lower.

### (Molecular Weight)

In one embodiment, the weight average molecular weight (Mw) of the substituted PPS resin is not limited as long as the substituted PPS resin has a desired dielectric loss tangent and/or a desired glass transition temperature, but is preferably 33000 or less. When the weight average molecular weight of the substituted PPS resin is 33000 or less, it may be less than 21000, 20000 or less, 18000 or less, 15000 or less, 13000 or less, 11000 or less, or 10000 or less.

When the weight average molecular weight of the substituted PPS resin is 33000 or less, the glass transition temperature tends to be a desired temperature.

The weight average molecular weight of the substituted PPS resin is preferably 1000 or more. When the weight average molecular weight of the substituted PPS resin is 1000 or more, it may be more than 1200, 1500 or more, 2000 or more, 2200 or more, 3000 or more, 3600 or more, 4000 or more, 4500 or more, 4900 or more, 5500 or more, 6000 or more, 7000 or more, 7300 or more, 8000 or more, 8400 or more, 10000 or more, 15000 or more, 20000 or more, 24000 or more, or 30000 or more.

When the weight average molecular weight of the substituted PPS resin is 1000 or more, the dielectric loss tangent and the dielectric constant are likely to be in desired ranges, and/or the storage elastic modulus at 260° C. is likely to be in a desired range, that is, good reflow resistance is likely to be exhibited.

The weight average molecular weight (Mw) is a value in terms of standard polystyrene determined by GPC measurement using a tetrahydrofuran solvent.

In one embodiment, the substituted PPS resin contains a constituent unit represented by General formula (I), and preferably has a dielectric loss tangent at 10 GHz of less than 0.002, a glass transition temperature of 250° C. or lower, and a weight average molecular weight of 33000 or less. The weight average molecular weight may be less than 21000.

In one embodiment, the substituted PPS resin contains a constituent unit represented by General formula (II), and preferably has a dielectric loss tangent at 10 GHz of less than 0.002, a glass transition temperature of 250° C. or lower, and a weight average molecular weight of 33000 or less. The weight average molecular weight may be less than 21000.

In one embodiment, the substituted PPS resin contains a terminal structure represented by General formula (III-a), (III-b), or (III), and preferably has a dielectric loss tangent at 10 GHz of less than 0.002, a glass transition temperature of 250° C. or lower, and a weight average molecular weight of 33000 or less. The weight average molecular weight may be less than 21000.

In one embodiment, the substituted PPS resin contains a terminal structure represented by General formula (III-a), (III-b), or (III), and preferably has a dielectric loss tangent at 10 GHz of less than 0.002, a glass transition temperature of 250° C. or lower, and a weight average molecular weight of 1000 or more and 33000 or less. The weight average molecular weight may be less than 21000.

(Storage Elastic Modulus) In one embodiment, the substituted PPS resin preferably has a storage elastic modulus at 260° C. of 1×10⁵ Pa or more. When the storage elastic modulus at 260° C. is 1×10⁵ or more, it may be 4×10⁵ Pa or more, 8×10⁵ Pa or more, 8.5×10⁵ Pa or more, 1×10⁶ Pa or more, 1.7×10⁶ Pa or more, 1×10⁵ Pa, 4×10⁵ Pa, 8×10⁵ Pa, 8.5×10⁵ Pa, 1×10⁶ Pa, or 1.7×10⁶ Pa.

When the storage elastic modulus at 260° C. of the substituted PPS resin is 1×10⁵ Pa or more, the substituted PPS resin easily exhibits good reflow resistance. When the storage elastic modulus at 260° C. of the substituted PPS resin is 1×10⁵ Pa or more, the storage elastic modulus at 260° C. of the resin composition containing the substituted PPS resin is likely to be 1×10⁵ Pa or more. Therefore, the resin composition containing the substituted PPS resin easily exhibits good reflow resistance, and/or the wiring board made of the resin composition easily exhibits good reflow resistance.

For example, when a printed wiring board is produced by mounting an electronic component such as a semiconductor on a wiring board such as a print circuit board and providing wiring, the electronic component is bonded and attached onto the wiring board with solder by heating in a reflow furnace.

When the storage elastic modulus at 260° C. of the substituted PPS resin is 1×10-5 Pa or more, the wiring board easily maintains the shape of the board even in the heating step in the reflow furnace, that is, the wiring board easily exhibits good reflow resistance.

The storage elastic modulus is adjusted by a method involving adjusting the content of the constituent unit represented by General formula (I), General formula (II), and/or General formula (III-a), (III-b), or (III) and containing an alkenyl group in the substituted PPS resin, a method involving adjusting the content of the alkenyl group in General formula (I), General formula (II), and/or General formula (III-a), (III-b), or (III), or a method involving adjusting the weight average molecular weight of the substituted PPS resin. The storage elastic modulus at 260° C. of the substituted PPS resin can be adjusted to 1×10⁻⁵ Pa or more by any of these methods or a combination thereof.

For example, for adjusting the storage elastic modulus at 260° C. of the substituted PPS resin to 1×10⁻⁵ Pa or more, the substituted PPS resin preferably contains the terminal structure represented by General formula (IlI-a), (III-b), or (III) at at least either one of the terminals of the resin, and more preferably contains the terminal structure represented by General formula (III-a), (III-b), or (III) at both of the terminals.

For example, when the content of the constituent unit having an alkenyl group-containing organic group in the substituted PPS resin is increased, the storage elastic modulus at 260° C. of the substituted PPS resin tends to be 1×10-5 Pa or more. For example, when the weight average molecular weight of the substituted PPS resin is 1000 or more, the storage elastic modulus at 260° C. of the substituted PPS resin is easily adjusted to 1×10⁻⁵ Pa or more.

The storage elastic modulus at 260° C. of the substituted PPS resin means a value as measured at a frequency of 1 Hz and 260° C. using a dynamic viscoelasticity measuring apparatus (RSA-G2, available from TA Instruments).

More specifically, the storage elastic modulus at 260° C. is measured at 260° C. using a dynamic viscoelasticity measuring apparatus (RSA-G2, available from TA Instruments) while the temperature is increased from room temperature at a rate of 5° C./min. A measurement sample (30 mm×3 mm) is cut out from a film having a uniform thickness in a range of from about 0.1 to 0.3 mm without causing a problem for measurement. The thickness of the sample is accurately determined, and the sample is used for measurement. Main measurement parameters involved in the measurement are as follows.
Measurement frequency: 10 Hz
Rate of temperature increase: 5° C./min
Sample measurement length: 15 mm
Strain: 0.05%

In one embodiment, the substituted PPS resin contains a constituent unit represented by General formula (I), and preferably has a dielectric loss tangent at 10 GHz of less than 0.002, a glass transition temperature of 250° C. or lower, a weight average molecular weight of 1000 or more and 33000 or less, and a storage elastic modulus at 260° C. of 1×10⁻⁵ Pa or more.

In one embodiment, the substituted PPS resin contains a constituent unit represented by General formula (II), and preferably has a dielectric loss tangent at 10 GHz of less than 0.002, a glass transition temperature of 250° C. or lower, a weight average molecular weight of 1000 or more and 33000 or less, and a storage elastic modulus at 260° C. of 1×10⁻⁵ Pa or more.

In one embodiment, the substituted PPS resin contains a terminal structure represented by General formula (111-a), (111-b), or (III), and preferably has a dielectric loss tangent at 10 GHz of less than 0.002, a glass transition temperature of 250° C. or lower, a weight average molecular weight of 1000 or more and 33000 or less, and a storage elastic modulus at 260° C. of 1×10⁻⁵ Pa or more.

In one embodiment, the substituted PPS resin contains a terminal structure represented by General formula (111-a), (III-b), or (III), and preferably has a dielectric loss tangent at 10 GHz of less than 0.002, a glass transition temperature of 250° C. or lower, a weight average molecular weight of 1000 or more and 33000 or less, and a storage elastic modulus at 260° C. of 1×10⁻⁵ Pa or more.

### [Resin Composition Containing Substituted PPS Resin for Wiring Board]

The resin composition according to the first embodiment is a resin composition containing a substituted PPS resin for a wiring board.

The resin composition may be composed only of the substituted PPS resin for a wiring board or may contain an additional component.

For example, the resin composition may contain, besides the substituted PPS resin for a wiring board, one or more components such as a curing catalyst, a flame retardant, a flame retardant synergist, a fiber reinforcing agent, a filler, a thermosetting additive, and/or a thermoplastic additive.

The content of the substituted PPS resin for a wiring board in the resin composition according to the present embodiment is not limited as long as the resin composition has a desired dielectric loss tangent, but is preferably 30 mass % or more. When the content is 30 mass % or more, it may be 40 mass % or more, 50 mass % or more, 60 mass % or more, 70 mass % or more, 80 mass % or more, 90 mass % or more, or 100 mass % or more.

When the content of the substituted PPS resin in the resin composition is 30 mass % or more, the dielectric loss tangent of the resin composition easily falls within a desired range. In addition, the resin composition easily exhibits thermosetting property, and easily exhibits good reflow resistance.

Since the resin composition contains the substituted PPS resin for a wiring board, the resin composition has a low dielectric loss tangent, exhibits thermosetting property, and/or exhibits good reflow resistance, and thus is suitably used as a material for a wiring board.

### [Production Method]

The method for producing the substituted PPS resin is not limited. The substituted PPS resin can be produced by a known method in the art, for example, by mixing one or more monomer materials required for producing a desired substituted PPS resin, and polymerizing the mixture under appropriate conditions to form a polymer structure.

More specifically, for example, 3,3′-dimethyldiphenyl disulfide, 2,3-dichloro-5,6-dicyano-parabenzoquinone (DDQ), trifluoromethanesulfonic acid, and dichloromethane may be added and stirred at room temperature for oxidative polymerization. A polymer can be produced by adding dropwise a reaction liquid into hydrochloric acid-acidified methanol, collecting the resultant powder by filtration, washing the powder with an aqueous potassium hydroxide solution and pure water, and vacuum drying the powder.

A substituted PPS resin containing a constituent unit having an alkenyl group-containing organic group can be produced by the following method. Here, an example of producing a substituted PPS resin containing a constituent unit having a vinyl group will be described.

Specifically, for example, poly(2,6-dimethyl-1,4-phenylene sulfide), N-bromosuccinimide (NBS), and AIBN are added and reacted under chlorobenzene reflux. After the reaction, the solution is cooled with ice water and the precipitated succinimide is filtered off with a glass filter. The filtrate is purified by precipitation with 5 wt % hydrochloric acid-acidified methanol to yield a purified bromo PPS product in which some of protons of methyl groups are bromo-substituted. Subsequently, the purified product and triphenylphosphine are mixed in THF, followed by heating under reflux for 24 hours. Thereafter, the reaction solution is cooled to room temperature, an aqueous formaldehyde solution is added to the reaction solution, and the mixture is stirred, whereby the precipitate disappears. Subsequently, potassium t-butoxide is added and reacted. After completion of the reaction, a vinyl-substituted PPS resin in which the methyl group has been converted to a vinyl group can be produced through purification by precipitation with hydrochloric acid-acidified methanol and recovery.

Alternatively, for example, DDQ is dispersed in dichloromethane, trifluoroacetic acid is added thereto, then bis(2,6-dimethylphenyl)disulfide is added thereto, and the mixture is stirred. Thereafter, 4,4′-divinyldiphenyl disulfide is further added, and the mixture is stirred, followed by purification by precipitation in hydrochloric acid-acidified methanol and filtration, to recover a crude product. Thereafter, the crude product is dissolved in chloroform and reprecipitated with hydrochloric acid-acidified methanol to yield a vinyl-substituted PPS resin having a vinyl group in a terminal structure of the resin in the form of a white powder.

For example, DDQ is dispersed in dichloromethane, trifluoroacetic acid is added thereto, then bis(2,6-dimethylphenyl)disulfide is added thereto, and the mixture is stirred. Thereafter, a polymer (white solid) can be produced through purification by precipitation in methanol. After tetrahydrofuran and 4-chloromethylstyrene) are added to the polymer and dissolved therein, an aqueous solution of sodium borohydride is added thereto and stirred.

Thereafter, the reaction liquid is subjected to purification by precipitation in methanol to produce a vinyl-substituted PPS resin having a vinyl group in a terminal structure of the resin.

Furthermore, for example, a vinyl-substituted PPS resin having a vinyl group in the terminal structure of the resin can be produced by subjecting bromo-terminated PPS and 4-vinylphenylboronic acid or vinylmagnesium bromide to a coupling reaction.

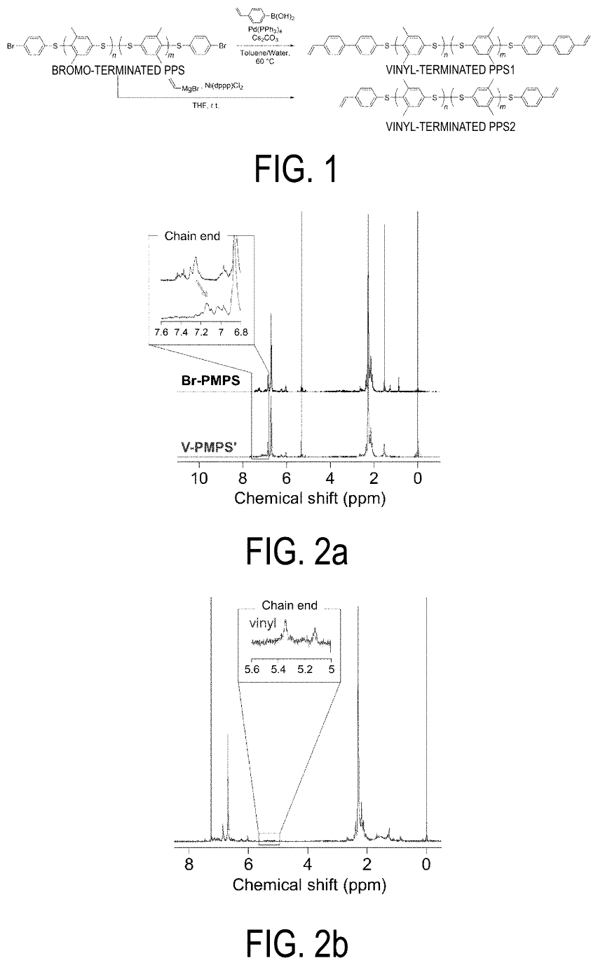

Specifically, for example, bromo-terminated PPS can be synthesized by adding poly(2,6-dimethyl-1,4-phenylene sulfide) to a solution of sulfonium cation (Br-DPS+) derived from Br-DPS (bis(4-bromophenyl)disulfide) in dichloromethane, followed by modification after polymerization. Poly(2,6-dimethyl-1,4-phenylene sulfide) and 4-vinylphenylboronic acid can be subjected to a Suzuki-Miyaura coupling reaction using a Pd catalyst to produce a vinyl-substituted PPS resin having a vinyl group in the terminal structure of the resin (“VINYL-TERMINATED PPS1” in FIG. 1). Alternatively, bromo-terminated PPS and vinylmagnesium bromide can be subjected to a Kumada-Tamao coupling reaction using Ni(dppp)Cl₂ ([1,3-bis(diphenylphosphino)propane]nickel(II) dichloride), followed by precipitation, recovery, and drying steps to produce a vinyl-substituted PPS resin having a vinyl group in the terminal structure of the resin in the form of a white powder (“VINYL-TERMINATED PPS2” in FIG. 1).

The method for producing the resin composition containing the substituted PPS resin is not limited, and the production can be carried out by equipment and a method generally used in preparing a resin composition. In general, the resin composition is often prepared in the form of a polymer solution (resin varnish) in which the substituted PPS resin is dissolved in an organic solvent.

The substituted PPS resin and additional components soluble in an organic solvent may be added to an organic solvent and mixed, for example, by stirring with a stirrer, for preparing such a resin varnish. In this case, heating may be performed, if necessary. Thereafter, a component (for example, an inorganic filler) insoluble in an organic solvent may be appropriately added, and the mixture may be dispersed until a predetermined dispersion state is achieved using a ball mill, a bead mill, a planetary mixer, a roll mill, or the like, to thereby prepare a resin varnish. Examples of the organic solvent are the same as those which will be described below in the section “Varnish”.

### [Product]

The substituted PPS resin for a wiring board and/or the resin composition containing the substituted PPS resin for a wiring board can be widely used as a material for a wiring board.

Although a product containing the substituted PPS resin and/or the resin composition is not limited, the product can be preferably used as an insulator component in a terminal of a mobile communication system based on such a characteristic that the product contains the substituted PPS resin containing a constituent unit represented by General formula (I) and thus is likely to have a low dielectric loss tangent. When the thermosetting property of the material is required as a product or in its production process, a substituted PPS resin and/or a resin composition exhibiting thermosetting property can be preferably used. Further, when the reflow resistance of the material is required as a product or in its production process, a substituted PPS resin and/or a resin composition exhibiting good reflow resistance can be preferably used.

Examples of products containing the substituted PPS resin and/or resin composition according to the present embodiment include a varnish containing the substituted PPS resin and/or the resin composition and a solvent, an interlayer insulating material containing the substituted PPS resin and/or the resin composition, a prepreg containing the substituted PPS resin and/or the resin composition and a base material, a metal-clad laminate containing the substituted PPS resin and/or the resin composition and a metal foil, a substrate containing the substituted PPS resin and/or the resin composition, a wiring board containing the substituted PPS resin and/or the resin composition, and a printed wiring board containing the wiring board and an electronic component.

Applications of these products are not limited, and the products can be used for various applications requiring high-speed communication. For example, the products may be mounted on network devices/terminals, servers, A-I processors, in-vehicle/aviation devices, home game machines, and the like.

Here, the above-mentioned products containing the substituted PPS resin and/or the resin composition each preferably have a dielectric loss tangent at 10 GHz of less than 0.002, and more preferably less than 0.001. When the dielectric loss tangent at 10 GHz of the product is less than 0.001, it may be less than 0.00095, less than 0.0009, or less than 0.00085.

When the dielectric loss tangent of the product is lower, the transmission loss is more easily suppressed.

In one embodiment, the printed wiring board including a wiring board (containing the substituted PPS resin and/or the resin composition) and an electronic component has a dielectric loss tangent at 10 GHz of preferably less than 0.002, and more preferably less than 0.001. When the dielectric loss tangent at 10 GHz of the printed wiring board is less than 0.001, it may be less than 0.00095, less than 0.0009, or less than 0.00085. When the dielectric loss tangent of the printed wiring board is lower, the transmission loss is more easily suppressed.

### (Varnish)

Examples of the varnish include a polymer solution (resin varnish) in which the substituted PPS resin and/or the resin composition is dissolved in an organic solvent. In this polymer solution, at least a part of the polymer may be dissolved at a liquid temperature of 25° C., but preferably, the polymer is completely dissolved.

The organic solvent used in the polymer solution is not limited and can be selected by those skilled in the art from organic solvents well known in the art. Examples of the organic solvent include acetone, ethyl acetate, cyclohexane, heptane, tetrahydrofuran, dimethylformamide, dimethylacetamide, dimethyl sulfoxide, ethylene glycol, cellosolve, carbitol, anisole, N-methylpyrrolidone, propylene glycol monomethyl ether, methyl ether acetate, toluene, cyclohexanone, methyl ethyl ketone, and methyl isobutyl ketone. One type selected from these organic solvents may be used, or two or more types selected therefrom may be used in combination.

The lower limit of the content of the substituted PPS resin and/or the resin composition in the polymer solution is not limited as long as a handleable and adequately producible polymer solution is produced. For example, the lower limit may be 5 mass % or more, 7 mass % or more, 10 mass % or more, or 15 mass % or more relative to 100 mass % of the polymer solution. Meanwhile, the upper limit of the content of the substituted PPS resin and/or the resin composition in the polymer solution may be, for example, 50 mass % or less, 45 mass % or less, 40 mass % or less, or 35 mass % or less relative to 100 mass % of the polymer solution.

### (Interlayer Insulating Material)

Examples of the interlayer insulating material include interlayer insulating materials used in printed wiring boards and the like. The interlayer insulating material can also be used as a material for a multilayer printed wiring board.

For example, a varnish containing the substituted PPS resin and/or the resin composition is an example of the interlayer insulating material, and a laminate structure of a multilayer print circuit board can also be prepared by applying the varnish to another material, evaporating the solvent, and forming an insulating film layer.

### (Prepreg)

An example of the prepreg is a prepreg produced by impregnating a base material with a varnish containing the substituted PPS resin and/or the resin composition and an organic solvent, followed by drying. The base material used in the prepreg is not limited and can be selected by those skilled in the art from materials well known in the art, and examples of the base material include natural fiber base materials, organic synthetic fiber base materials, and inorganic fiber base materials.

### (Metal-Clad Laminate)

Examples of the metal-clad laminate include a metal-clad laminate containing the prepreg. Such a metal-clad laminate can be produced, for example, by stacking a plurality of prepregs, stacking a metal foil on one surface or both surfaces of the stacked product, followed by press-molding under heat and pressure. Examples of the metal foil include a copper foil, an aluminum foil, a tin foil, a gold foil, a silver foil, a platinum foil, and a nickel foil. The metal foil can be selected by those skilled in the art in accordance with the properties and applications required of the metal-clad laminate.

### (Substrate)

The substrate is a pedestal used together with a semiconductor chip such as a CPU or a memory for protecting the semiconductor chip and mounting it on a print circuit board (PCB). For example, the substrate may be a board portion in FC-BGA (Flip Chip-Ball Grid Array), FC-CSP (Flip Chip Chip Scale Package), or the like.

### (Wiring Board)

The wiring board is a board to be attached with an electronic component such as a semiconductor and to be provided with wiring, and is not limited by its structure and/or application. In the present specification, the wiring board includes a portion other than an electronic component such as a semiconductor in a printed wiring board, and, as the wiring board, a print circuit board (PCB) of the printed wiring board can be exemplified. The print circuit board may be, for example, a multilayer print circuit board described above in “Interlayer Insulating Material”. The print circuit board includes all of a rigid board, a flexible board, a rigid flexible board, a metal-based board, and the like. An electronic component can be mounted on any of these print circuit boards, to form a printed wiring board.

### (Printed Wiring Board)

The printed wiring board is not limited by its structure and/or application as long as it includes the wiring board and the electronic component. For example, the printed wiring board may be produced by mounting an electronic component on any print circuit board such as a rigid board, a flexible board, a rigid flexible board, or a metal-based board.

Examples of the electronic component include, but are not limited to, a semiconductor chip, a resistor, and a capacitor. As a structure, for example, wiring or an electronic component may be mounted on one surface or both surfaces of a wiring board (print circuit board), or wiring or an electronic component may be mounted between layers of a wiring board having a multilayer structure.

As applications, for example, a rigid printed wiring board in which an electronic component is mounted on a rigid board can be used in a terminal of a mobile communication system, a base station, a server, a router, a millimeter wave radar, a probe card, or the like, and a flexible printed wiring board in which an electronic component is mounted on a flexible board can be used in a connection cable, an antenna, an antenna cable, or the like.

### Second Embodiment (Substituted PPS Resin Having Low Dielectric Loss Tangent)

### [Substituted PPS Resin Having Dielectric Loss Tangent at 10 GHz of Less Than 0.002]

The resin according to a second embodiment is a substituted PPS resin containing a constituent unit represented by General formula (I) and having a dielectric loss tangent at 10 GHz of less than 0.002.

General formula (I):

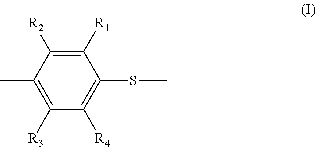

[In formula (I), R₁, R₂, R₃, and R₄ are each independently H, an alkyl group, an alkoxy group, or an alkenyl group-containing organic group, and one or more of R₁, R₂, R₃, and R₄ are an alkyl group or an alkoxy groups.]

### (Dielectric Loss Tangent)

The substituted PPS resin according to the present embodiment has a dielectric loss tangent at 10 GHz of less than 0.002. As a result, the dielectric loss tangent at 10 GHz of the resin composition containing the substituted PPS resin is likely to be less than 0.002.

The range, preferable range, and the like of the dielectric constant and the method for adjusting the dielectric constant in the second embodiment are the same as those described in “Dielectric Loss Tangent” in the first embodiment.

When the substituted PPS resin has a lower dielectric loss tangent, the transmission loss is more easily suppressed when the substituted PPS resin is used as a material for a wiring board or the like.

### (Dielectric Constant)

The range, preferable range, and the like of the dielectric constant and the method for adjusting the dielectric constant in the second embodiment are the same as those described in “Dielectric Constant” in the first embodiment.

When the substituted PPS resin has a lower dielectric constant, the transmission loss is more easily suppressed when the substituted PPS resin or the resin composition containing the substituted PPS resin is used as a material for a wiring board or the like.

### (Measurement of Dielectric Loss Tangent and Dielectric Constant)

In the second embodiment, the dielectric loss tangent and the dielectric constant can be measured as described in “Measurement of Dielectric Loss Tangent and Dielectric Constant” in the first embodiment.

In one embodiment, the substituted PPS resin contains a constituent unit represented by General formula (I), and preferably has a dielectric loss tangent at 10 GHz of less than 0.002 and a dielectric constant at 10 GHz of less than 3.00.

### (Substituted PPS Resin Containing Constituent Unit Having Alkyl Group or Alkoxy Group)

The substituted PPS resin contains a constituent unit represented by General formula (I).

### General Formula (I):

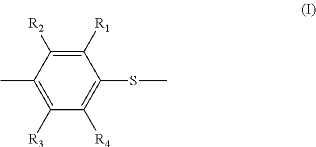

[wherein R₁, R₂, R₃, and R₄ are each independently H, an alkyl group, an alkoxy group, or an alkenyl group-containing organic group, and one or more of R₁, R₂, R₃, and R₄ are an alkyl group or an alkoxy group.]

Examples and preferred examples of the “substituted PPS resin containing a constituent unit having an alkyl group or an alkoxy group” in the second embodiment are the same as those described in “Substituted PPS Resin Containing Constituent Unit Having Alkyl Group or Alkoxy Group” in the first embodiment.

### (Substituted PPS Resin Containing Constituent Unit Having Alkenyl Group-Containing Organic Group)

In one embodiment, the substituted PPS resin according to the second embodiment may contain a constituent unit represented by General formula (II):

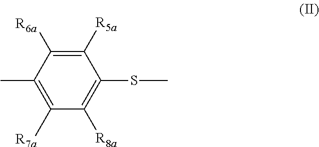

[wherein R₅ₐ, R₆ₐ, R₇ₐ, and R₈ₐ are each independently H, an alkyl group, an alkoxy group, or an alkenyl group-containing organic group, and one or more of R₅ₐ, R₆ₐ, R₇ₐ, and R₈ₐ are an alkenyl group-containing organic group]; and/or a terminal structure represented by General formula (III):

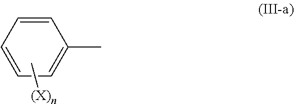

[wherein Xs are each independently H, an alkyl group, an alkoxy group, or an alkenyl group-containing organic group, one or more of Xs are an alkenyl group-containing organic group, and n is an integer of from 1 to 5].

The terminal structure represented by General formula (III-a) may be a terminal structure represented by General formula (III-b):

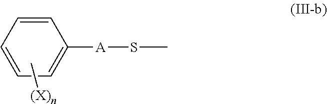

[wherein Xs are each independently H, an alkyl group, an alkoxy group, or an alkenyl group-containing organic group, one or more of Xs are an alkenyl group-containing organic group, n is an integer of from 1 to 5, and A is represented by General formula (IV):

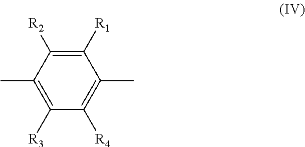

{wherein R₁, R₂, R₃, and R₄ are each independently H, an alkyl group, an alkoxy group, or an alkenyl group-containing organic group, and one or more of R₁, R₂, R₃, and R₄ are an alkyl group or an alkoxy group}].

The terminal structure represented by General formula (III-a) may be a terminal structure represented by General formula (III):

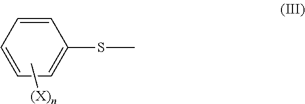

[wherein Xs are each independently H, an alkyl group, an alkoxy group, or an alkenyl group-containing organic group, one or more of Xs are an alkenyl group-containing organic group, and n is an integer of from 1 to 5].

Examples and preferred examples of the “substituted PPS resin containing a constituent unit having an alkenyl group-containing organic group” in the second embodiment are the same as those described in “Substituted PPS Resin Containing Constituent Unit Having Alkenyl Group-Containing Organic Group” in the first embodiment.

In one embodiment, the substituted PPS resin contains a constituent unit represented by General formula (I) and has a dielectric loss tangent at 10 GHz of less than 0.002, and preferably contains a constituent unit represented by General formula (II) and/or a terminal structure represented by General formula (III-a), (III-b), or (III).

When one or more alkenyl group-containing organic groups are contained in General formula (II) and/or General formula (Ill-a), (III-b), or (III), the substituted PPS resin containing the constituent unit represented by General formula (II) and/or the terminal structure represented by General formula (III-a), (III-b), or (III) easily exhibits thermosetting property. As a result, the resin composition containing the substituted PPS resin easily exhibits thermosetting property.

### (Polymer Structure)

Examples and preferred examples of the “polymer structure” in the second embodiment are the same as those described in “Polymer Structure” in the first embodiment.

### (Glass Transition Temperature)

Examples and preferred examples of the “glass transition temperature” in the second embodiment and a method for adjusting the glass transition temperature are the same as those described in “Glass Transition Temperature” in the first embodiment.

### (Molecular Weight)

Examples and preferred examples of the “molecular weight” in the second embodiment are the same as those described in “Molecular Weight” in the first embodiment.

### (Storage Elastic Modulus)

Examples and preferred examples of the “storage elastic modulus” in the second embodiment and a method for adjusting the storage elastic modulus are the same as those described in “Storage Elastic Modulus” in the first embodiment.

### [Resin Composition Containing Substituted PPS Resin]

The resin composition according to the second embodiment is a resin composition containing a substituted PPS resin having a dielectric loss tangent at 10 GHz of less than 0.002.

The resin composition may be composed only of the substituted PPS resin or may contain an additional component.

For example, the resin composition may contain, besides the substituted PPS resin having a dielectric loss tangent at 10 GHz of less than 0.002, one or more components such as a curing catalyst, a flame retardant, a flame retardant synergist, a fiber reinforcing agent, a filler, a thermosetting additive, and/or a thermoplastic additive.

The content of the substituted PPS resin having a dielectric loss tangent at 10 GHz of less than 0.002 in the resin composition according to the present embodiment is not limited as long as the resin composition has a desired dielectric loss tangent, but is preferably 30 mass % or more. When the content is 30 mass % or more, it may be 40 mass % or more, 50 mass % or more, 60 mass % or more, 70 mass % or more, 80 mass % or more, 90 mass % or more, or 100 mass % or more.

When the content of the substituted PPS resin in the resin composition is 30 mass % or more, the dielectric loss tangent of the resin composition easily falls within a desired range. In addition, the resin composition easily exhibits thermosetting property, and easily exhibits good reflow resistance.

Since the resin composition contains the substituted PPS resin having a dielectric loss tangent at 10 GHz of less than 0.002, the resin composition has a low dielectric loss tangent, exhibits thermosetting property, and/or exhibits good reflow resistance, and thus is suitably used as a material for a wiring board or the like.

### [Production Method]

The method for producing the substituted PPS resin in the second embodiment is the same as that described in “Production Method” in the first embodiment.

### [Product]

The substituted PPS resin having a dielectric loss tangent at 10 GHz of less than 0.002 and/or the resin composition containing the substituted PPS resin having a dielectric loss tangent at 10 GHz of less than 0.002 according to the second embodiment can be widely used as a material for a wiring board or the like.

The wiring board includes all portions other than an electronic component such as a semiconductor in a printed wiring board (also referred to as printed circuit board). In general, the printed wiring board has a structure in which a semiconductor package including an electronic component such as a semiconductor mounted on a pedestal called substrate is mounted on a print circuit board (PCB), but the “board” “for a wiring board” also includes a substrate.

Although a product containing the substituted PPS resin and/or the resin composition is not limited, the product can be preferably used as an insulator component in a terminal of a mobile communication system based on such a characteristic that the product contains the substituted PPS resin containing a constituent unit represented by General formula (I) and thus is likely to have a low dielectric loss tangent. When the thermosetting property of the material is required as a product or in its production process, the resin composition according to the present embodiment exhibiting thermosetting property can be preferably used. Further, when the reflow resistance of the material is required as a product or in its production process, a substituted PPS resin and/or a resin composition exhibiting good reflow resistance can be preferably used.

Examples of products containing the substituted PPS resin and/or resin composition according to the present embodiment include a varnish containing the substituted PPS resin and/or the resin composition and a solvent, an interlayer insulating material containing the substituted PPS resin and/or the resin composition, a prepreg containing the substituted PPS resin and/or the resin composition and a base material, a metal-clad laminate containing the substituted PPS resin and/or the resin composition and a metal foil, a substrate containing the substituted PPS resin and/or the resin composition, a wiring board containing the substituted PPS resin and/or the resin composition, and a printed wiring board containing the wiring board and an electronic component.

Applications of these products are not limited, and the products can be used for various applications requiring high-speed communication. For example, the products may be mounted on network devices/terminals, servers, AI processors, in-vehicle/aviation devices, home game machines, and the like.

Here, the above-mentioned products containing the substituted PPS resin and/or the resin composition each preferably have a dielectric loss tangent at 10 GHz of less than 0.002, and more preferably less than 0.001. When the dielectric loss tangent at 10 GHz of the product is less than 0.001, it may be less than 0.00095, less than 0.0009, or less than 0.00085.

When the dielectric loss tangent of the product is lower, the transmission loss is more easily suppressed.

In one embodiment, the printed wiring board including a wiring board (containing the substituted PPS resin and/or the resin composition) and an electronic component has a dielectric loss tangent at 10 GHz of preferably less than 0.002, and more preferably less than 0.001. When the dielectric loss tangent at 10 GHz of the printed wiring board is less than 0.001, it may be less than 0.00095, less than 0.0009, or less than 0.00085. When the dielectric loss tangent of the printed wiring board is lower, the transmission loss is more easily suppressed.

### (Varnish)

Examples and preferred examples of the “varnish” in the second embodiment are the same as those described in “Varnish” in the first embodiment.

### (Interlayer Insulating Material)

Examples and preferred examples of the “interlayer insulating material” in the second embodiment are the same as those described in “Interlayer Insulating Material” in the first embodiment.

### (Prepreg)

Examples and preferred examples of the “prepreg” in the second embodiment are the same as those described in “Prepreg” in the first embodiment.

### (Metal-Clad Laminate)

Examples and preferred examples of the “metal-clad laminate” in the second embodiment are the same as those described in “Metal-Clad Laminate” in the first embodiment.

### (Substrate)

Examples and preferred examples of the “substrate” in the second embodiment are the same as those described in “Substrate” in the first embodiment.

(Wiring board)

Examples and preferred examples of the “wiring board” in the second embodiment are the same as those described in “Wiring Board” in the first embodiment.

### (Printed Wiring Board)

Examples and preferred examples of the “printed wiring board” in the second embodiment are the same as those described in “Printed Wiring Board” in the first embodiment.

### Third Embodiment (Substituted PPS Resin Having Terminal Structure Containing Alkenyl Group-Containing Organic Group)

### [Substituted PPS Resin](Substituted PPS Resin Having Terminal Structure Containing Alkenyl Group-Containing Organic Group)

The resin according to the third embodiment is a substituted PPS resin containing a terminal structure represented by General formula (III-a).

General formula (III-a):

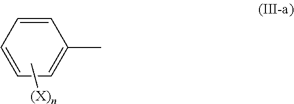

[wherein Xs are each independently H, an alkyl group, an alkoxy group, or an alkenyl group-containing organic group, one or more of Xs are an alkenyl group-containing organic group, and n is an integer of from 1 to 5.]

The terminal structure represented by General formula (III-a) may be a terminal structure represented by General formula (III-b):

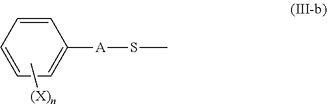

[wherein Xs are each independently H, an alkyl group, an alkoxy group, or an alkenyl group-containing organic group, one or more of Xs are an alkenyl group-containing organic group, n is an integer of from 1 to 5, and A is represented by General formula (IV):

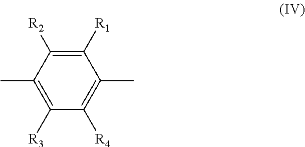

{wherein R₁, R₂, R₃, and R₄ are each independently H, an alkyl group, 20 an alkoxy group, or an alkenyl group-containing organic group, and one or more of R₁, R₂, R₃, and R₄ are an alkyl group or an alkoxy group}].

The terminal structure represented by General formula (Ill-a) may be a terminal structure represented by General formula (III):

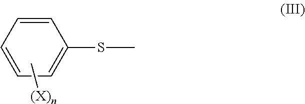

[wherein Xs are each independently H, an alkyl group, an alkoxy group, or an alkenyl group-containing organic group, one or more of Xs are an alkenyl group-containing organic group, and n is an integer of from 1 to 5].

In the third embodiment, the terminal structures represented by General formulae (III-a), (III-b), and (III) represent that one or more of substituents are an alkenyl group-containing organic group in the terminal structures located at one or both terminals of the resin among the constituent units contained in the substituted PPS resin.

The substituted PPS resin according to the third embodiment contains a phenylene group which may have a substituent as one terminal and/or at least a part of a constituent unit other than the terminal. Examples of the substituent of the phenylene group include H, an alkyl group, an alkoxy group, and an alkenyl group-containing organic group. The phenylene group which may have a substituent is preferably a constituent unit represented by General formula (I) and/or General formula (II) described in “Substituted PPS Resin Containing Constituent Unit Having Alkyl Group or Alkoxy Group” of the present embodiment.

Examples and preferred examples of the alkyl group, alkoxy group, and alkenyl group-containing organic group in General formulae (Ill-a), (III-b), and (III) include the alkyl group, alkoxy group, and alkenyl group-containing organic group exemplified in the description of General formula (I) of the first embodiment. The number of carbons of the alkyl group or the alkoxy group may also be the number of carbons exemplified in the description of General formula (I) of the first embodiment.

The number of carbons of the alkenyl group in General formula (III) may be the number of carbons exemplified in the descriptions of General formulae (Ill-a), (III-b), and (III) of the first embodiment.

Here, the position of substitution with the alkenyl group-containing organic group in General formulae (Ill-a), (III-b), and (III) can be the substitution position described in General formulae (Ill-a), (III-b), and (III) of the first embodiment.

When one or more alkenyl group-containing organic groups are contained in General formulae (III-a), (III-b), and (III), the substituted PPS resin containing the terminal structure represented by General formula (III) easily exhibits thermosetting property, and easily exhibits good reflow resistance. As a result, the resin composition containing the substituted PPS resin easily exhibits thermosetting property and good reflow resistance.

### (Substituted PPS Resin Containing Constituent Unit Having Alkyl Group or Alkoxy Group)

In one embodiment, the substituted PPS resin according to the third embodiment may contain a constituent unit represented by General formula (I):

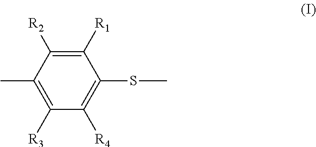

[wherein R₁, R₂, R₃, and R₄ are each independently H, an alkyl group, an alkoxy group, or an alkenyl group-containing organic group, and one or more of R₁, R₂, R₃, and R₄ are an alkyl group or an alkoxy group].

Examples and preferred examples of the “substituted PPS resin containing a constituent unit having an alkyl group or an alkoxy group” in the third embodiment are the same as those described in “Substituted PPS Resin Containing Constituent Unit Having Alkyl Group or Alkoxy Group” in the first embodiment.

In one embodiment, the substituted PPS resin preferably contains a terminal structure represented by General formula (III) and contains a constituent unit represented by General formula (I).

When one or more alkyl groups or alkoxy groups are contained in General formula (I), the dielectric loss tangent of the substituted PPS resin containing the constituent unit represented by General formula (I) tends to be low. As a result, the dielectric loss tangent of the resin composition containing the substituted PPS resin tends to be low.

### (Substituted PPS Resin Containing Constituent Unit Having Alkenyl Group-Containing Organic Group)

In one embodiment, the substituted PPS resin may contain a constituent unit represented by General formula (II):

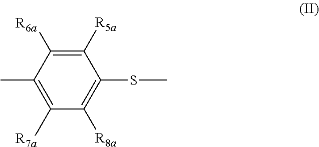

[wherein R₅ₐ, R₆ₐ, R₇ₐ, and R₈ₐ are each independently H, an alkyl group, an alkoxy group, or an alkenyl group-containing organic group, and one or more of R₅ₐ, R₆ₐ, R₇ₐ, and R₈ₐ are an alkenyl group-containing organic group].

The constituent unit represented by General formula (II) represents that one or more of substituents are an alkenyl group-containing organic group in constituent units other than the constituent unit located at the terminal of the resin among the constituent units contained in the substituted PPS resin.

Examples and preferred examples of the alkyl group, alkoxy group, and alkenyl group-containing organic group in General formula (II) in the third embodiment include the alkyl group, alkoxy group, and alkenyl group-containing organic group exemplified in the description of General formula (I) of the first embodiment. The number of carbons of the alkyl group or the alkoxy group may also be the number of carbons exemplified in the description of General formula (I) of the first embodiment.

The number of carbons of the alkenyl group-containing organic group in General formula (II) may be the number of carbons exemplified in the description of General formula (II) of the first embodiment.

Here, the position of substitution with the alkenyl group-containing organic group in General formula (II) can be the substitution position described in General formula (II) of the first embodiment.

When one or more alkenyl group-containing organic groups are contained in General formula (II), the substituted PPS resin containing the constituent unit represented by General formula (II) easily exhibits thermosetting property. As a result, the resin composition containing the substituted PPS resin easily exhibits thermosetting property.

### (Polymer Structure)

The substituted PPS resin has a polymer structure including two or more constituent units (monomer units) capable of constituting the resin. The substituted PPS resin according to the third embodiment contains a terminal structure represented by General formula (III-a), (III-b), or (III) as both or one of the terminals of the resin. The substituted PPS resin may contain one or more constituent units represented by a general formula other than General formulae (III-a), (III-b), and (III).

The terminal structure represented by General formula (Ill-a), (III-b), or (III) may be one type of terminal structure, that is, both terminals of the resin have the same general formula and have the same substituents, or may be two types of terminal structures as long as they are represented by General formula (III-a), (III-b), or (III), that is, the respective terminals of the resin may have different structures. The terminal structure represented by General formula (III-a), (III-b), or (III) includes two or more terminal structures having different combinations of substituents in five Xs as exemplified in the description of General formula (III-a), (III-b), or (III). From the viewpoint of easily exhibiting thermosetting property and/or easily improving reflow resistance, the terminal structure may be one type of terminal structure or two types of terminal structures. However, in consideration of ease of synthesis of the substituted PPS resin, preferably, both terminals of the resin have one type of terminal structure, that is, the terminals have the same general formula and have the same substituent.

Here, the one or more constituent units represented by a general formula other than General formulae (III-a), (III-b), and (III) include, but are not limited to, a constituent unit represented by General formula (I), a constituent unit represented by General formula (II), and an unsubstituted PPS (PPS in which all substituents of General formula (I) are H) unit.

Here, the constituent unit represented by General formula (I) may be one constituent unit, or may be two or more constituent units as long as they are represented by General formula (I). The constituent unit represented by General formula (I) includes two or more constituent units having different combinations of substituents in R₁, R₂, R₃, and R₄ as exemplified in the description of General formula (I) of the first embodiment.

The constituent unit represented by General formula (II) may be one constituent unit, or may be two or more constituent units as long as they are represented by General formula (II). The constituent unit represented by General formula (II) includes two or more constituent units having different combinations of substituents in R₅ₐ, R₆ₐ, R₇ₐ, and R₈ₐ as exemplified in the description of General formula (II) of the first embodiment.

In the substituted PPS resin, the order of bonding of the constituent units is not limited. For example, the constituent units represented by General formula (I) having the same combination of substituents may be adjacent to each other; the constituent units represented by General formula (II) having the same combination of substituents may be adjacent to each other; the constituent units represented by General formula (I) having different combinations of substituents may be adjacent to each other; the constituent units represented by General formula (II) having different combinations of substituents may be adjacent to each other; the constituent unit represented by General formula (I) may be adjacent to the constituent unit represented by General formula (II); or the constituent unit represented by General formula (I) or (II) may be adjacent to a constituent unit other than the constituent unit represented by General formula (I) or (II). Further, the terminal structure represented by General formula (III-a), (III-b), or (III) may be bonded to both or one of the terminals of the plurality of constituent units bonded in any order.

In one embodiment, the substituted PPS resin may contain a constituent unit represented by General formula (III-a), (III-b), or (III) wherein the group at at least one of 2-position, 3-position, 4-position, or 5-position is an alkenyl group-containing organic group having 2 or 3 carbons, and Xs which are not an alkenyl group-containing organic group are each H or an alkyl group having from 1 to 5 carbons, and a constituent unit represented by General formula (I) wherein R₂ and R₃ are an alkyl group having from 1 to 5 carbons, and R₁ and R₄ are H, or may contain a constituent unit represented by General formula (III-a), (III-b), or (III) wherein the group at at least one of 2-position, 3-position, 4-position, or 5-position is a vinyl group and Xs which are not a vinyl group are each H or a methyl group, and a constituent unit represented by General formula (I) wherein R₂ or R₃ is a methyl group and R₁ and R₄ are H.

In one embodiment, the substituted PPS resin may contain a constituent unit represented by General formula (III-a), (III-b), or (III) wherein the group at at least either one of 3-position and 5-position is an alkenyl group-containing organic group having 2 or 3 carbons, and Xs which are not an alkenyl group-containing organic group are each H or an alkyl group having from 1 to 5 carbons, and a constituent unit represented by General formula (I) wherein R₂ and R₃ are an alkyl group having from 1 to 5 carbons and R₁ and R₄ are H, or may contain a constituent unit represented by General formula (III) wherein the group at at least either one of 3-position and 5-position is a vinyl group and Xs which are not a vinyl group are each H or a methyl group, and a constituent unit represented by General formula (I) wherein R₂ or R₃ is a methyl group and R₁ and R₄ are H.

In one embodiment, the substituted PPS resin may have an alkenyl group-containing organic group at any substitution position in General formula (I), General formula (II), and/or General formula (III-a), (III-b), or (III), and the alkenyl group-containing organic group may have 2 or 3 carbons, and may be a vinyl group.

In one embodiment, the substituted PPS resin may be a 3,5-dimethyl PPS resin which may have one or more alkenyl group-containing organic groups having 2 or 3 carbons in both or one of the terminal structures. In one embodiment, the substituted PPS resin may be a 3,5-dimethyl PPS resin which may have one or more vinyl groups in both or one of the terminal structures.

In one embodiment, the content of the constituent unit represented by General formula (I) or the contents of the constituent unit represented by General formula (I) and the constituent unit represented by General formula (II) in the substituted PPS resin are not limited as long as the substituted PPS resin and/or the resin composition containing the substituted PPS resin has a desired dielectric loss tangent. The content of the constituent unit containing an alkyl group and/or an alkoxy group in the substituted PPS resin is preferably 30 mol % or more. When the content is 30 mol % or more, it may be 40 mol % or more, 50 mol % or more, 60 mol % or more, 70 mol % or more, 80 mol % or more, 90 mol % or more, or 100 mol %.

When the content of the constituent unit containing an alkyl group and/or an alkoxy group in the substituted PPS resin is 30 mol % or more, the dielectric loss tangent of the substituted PPS resin is likely to be in a desired range, and as a result, the dielectric loss tangent of the resin composition containing the substituted PPS resin is likely to be in a desired range.

In one embodiment, the content of the constituent unit having an alkenyl group-containing organic group in the substituted PPS resin is not limited as long as the substituted PPS resin and/or the resin composition containing the substituted PPS resin exhibits desired thermosetting property, but the upper limit of the content is 20 mol % or less, preferably 18 mol % or less, more preferably from 1 to 18 mol %, even more preferably from 2 to 10 mol %, and still even more preferably from 2 to 7% mol %. When the content is 18 mol % or less, it may be 15 mol % or less, 10 mol % or less, 7 mol % or less, 5 mol % or less, 4 mol % or less, 3 mol % or less, or 1 mol or less.

The lower limit of the content of the constituent unit having an alkenyl group-containing organic group in the substituted PPS resin is 1 constituent unit. Here, when the content of the constituent unit having an alkenyl group-containing organic group in the substituted PPS resin according to the third embodiment is 1 constituent unit, either one of the terminal structures of the substituted PPS resin is a terminal structure having an alkenyl group-containing organic group. Even when only 1 constituent unit of the substituted PPS resin has an alkenyl group-containing organic group, the substituted PPS resin easily exhibits thermosetting property because the constituent unit is a terminal structure.

When the lower limit of the content of the constituent unit having an alkenyl group-containing organic group in the substituted PPS resin is 1 constituent unit or more, the lower limit may be 2 constituent units or more, 0.1 mol % or more, 0.2 mol % or more, 0.5 mol % or more, or 0.8 mol % or more.

In one embodiment, the content of the constituent unit having an alkenyl group-containing organic group in the substituted PPS resin may be in a range obtained by combining any of the upper limits and any of the lower limits described above.

For example, the content of the constituent unit having an alkenyl group-containing organic group in the substituted PPS resin may be 1 constituent unit or more and 18 mol % or less, 1 constituent unit or more and 15 mol % or less, 1 constituent unit or more and 10 mol % or less, 1 constituent unit or more and 7 mol % or less, 1 constituent unit or more and 5 mol % or less, 1 constituent unit or more and 4 mol % or less, 1 constituent unit or more and 3 mol % or less, or 1 constituent unit or more and 1 mol % or less. The content may be 2 constituent units or more and 18 mol % or less, 2 constituent units or more and 15 mol % or less, 2 constituent units or more and 10 mol % or less, 2 constituent units or more and 7 mol % or less, 2 constituent units or more and 5 mol % or less, 2 constituent units or more and 4 mol % or less, 2 constituent units or more and 3 mol % or less, or 2 constituent units or more and 1 mol % or less. The content may be 0.1 mol % or more and 18 mol % or less, 0.1 mol % or more and 15 mol % or less, 0.1 mol % or more and 10 mol % or less, 0.1 mol % or more and 7 mol % or less, 0.1 mol % or more and 5 mol % or less, 0.1 mol % or more and 4 mol % or less, 0.1 mol % or more and 3 mol % or less, or 0.1 mol % or more and 1 mol % or less. The content may be 0.2 mol % or more and 18 mol % or less, 0.2 mol % or more and 15 mol % or less, 0.2 mol % or more and 10 mol % or less, 0.2 mol % or more and 7 mol % or less, 0.2 mol % or more and 5 mol % or less, 0.2 mol % or more and 4 mol % or less, 0.2 mol % or more and 3 mol % or less, or 0.2 mol % or more and 1 mol % or less. The content may be 0.5 mol % or more and 18 mol % or less, 0.5 mol % or more and 15 mol % or less, 0.5 mol % or more and 10 mol % or less, 0.5 mol % or more and 7 mol % or less, 0.5 mol % or more and 5 mol % or less, 0.5 mol % or more and 4 mol % or less, 0.5 mol % or more and 3 mol % or less, or 0.5 mol % or more and 1 mol % or less.

The content may be 0.8 mol % or more and 18 mol % or less, 0.8 mol % or more and 15 mol % or less, 0.8 mol % or more and 10 mol % or less, 0.8 mol % or more and 7 mol % or less, 0.8 mol % or more and 5 mol % or less, 0.8 mol % or more and 4 mol % or less, 0.8 mol % or more and 3 mol % or less, or 0.8 mol % or more and 1 mol % or less.

When the content of the constituent unit having an alkenyl group-containing organic group in the substituted PPS resin is 1 constituent unit or more and 20 mol % or less, the substituted PPS resin easily exhibits thermosetting property and/or good reflow resistance. As a result, the resin composition containing the substituted PPS resin is likely to exhibit thermosetting property and/or good reflow resistance.

### (Dielectric Loss Tangent)

The range, preferable range, and the like of the dielectric constant and the method for adjusting the dielectric constant in the third embodiment are the same as those described in “Dielectric Loss Tangent” in the first embodiment.

When the substituted PPS resin has a lower dielectric loss tangent, the transmission loss is more easily suppressed when the substituted PPS resin is used as a material for a wiring board or the like.

### (Dielectric Constant)

The range, preferable range, and the like of the dielectric constant and the method for adjusting the dielectric constant in the third embodiment are the same as those described in “Dielectric Constant” in the first embodiment.

When the substituted PPS resin has a lower dielectric constant, the transmission loss is more easily suppressed when the substituted PPS resin or the resin composition containing the substituted PPS resin is used as a material for a wiring board or the like.

### (Measurement of Dielectric Loss Tangent and Dielectric Constant)

In the third embodiment, the dielectric loss tangent and the dielectric constant can be measured as described in “Measurement of Dielectric Loss Tangent and Dielectric Constant” in the first embodiment.

In one embodiment, the substituted PPS resin contains a terminal structure represented by General formula (III-a), (III-b), or (III), and preferably has a dielectric loss tangent at 10 GHz of less than 0.002. In one embodiment, furthermore, the dielectric constant at 10 GHz may be less than 3.00.

In one embodiment, the substituted PPS resin contains a terminal structure represented by General formula (Ill-a), (III-b), or (III) and a constituent unit represented by General formula (I), and preferably has a dielectric loss tangent at 10 GHz of less than 0.002. In one embodiment, furthermore, the dielectric constant at 10 GHz may be less than 3.00.

In one embodiment, the substituted PPS resin contains a terminal structure represented by General formula (III-a), (III-b), or (III) and a constituent unit represented by General formula (II), and preferably has a dielectric loss tangent at 10 GHz of less than 0.002. In one embodiment, furthermore, the dielectric constant at 10 GHz may be less than 3.00.

### (Glass Transition Temperature)

Examples and preferred examples of the “glass transition temperature” in the third embodiment and a method for adjusting the glass transition temperature are the same as those described in “Glass Transition Temperature” in the first embodiment.

In one embodiment, the substituted PPS resin contains a terminal structure represented by General formula (III-a), (III-b), or (III), and preferably has a dielectric loss tangent at 10 GHz of less than 0.002 and a glass transition temperature of 250° C. or lower.

In one embodiment, the substituted PPS resin contains a terminal structure represented by General formula (111-a), (111-b), or (III) and a constituent unit represented by General formula (I), and preferably has a dielectric loss tangent at 10 GHz of less than 0.002 and a glass transition temperature of 250° C. or lower.

In one embodiment, the substituted PPS resin contains a terminal structure represented by General formula (111-a), (III-b), or (III) and a constituent unit represented by General formula (II), and preferably has a dielectric loss tangent at 10 GHz of less than 0.002, and have a glass transition temperature of 250° C. or lower.

### (Molecular Weight)

Examples and preferred examples of the “molecular weight” in the third embodiment are the same as those described in “Molecular Weight” in the first embodiment.

In one embodiment, the substituted PPS resin contains a constituent unit represented by General formula (111-a), (111-b), or (III), and preferably has a dielectric loss tangent at 10 GHz of less than 0.002, a glass transition temperature of 250° C. or lower, and a weight average molecular weight of 33000 or less. The weight average molecular weight may be less than 21000.

In one embodiment, the substituted PPS resin contains constituent units represented by General formula (111-a), (111-b), or (III) and General formula (I), and preferably has a dielectric loss tangent at 10 GHz of less than 0.002, a glass transition temperature of 250° C. or lower, and a weight average molecular weight of 33000 or less. The weight average molecular weight may be less than 21000.

In one embodiment, the substituted PPS resin contains a terminal structure represented by General formula (111-a), (111-b), or (III) or General formula (II), and preferably has a dielectric loss tangent at 10 GHz of less than 0.002, a glass transition temperature of 250° C. or lower, and a weight average molecular weight of 33000 or less. The weight average molecular weight may be less than 21000.

In one embodiment, the substituted PPS resin contains a terminal structure represented by General formula (111-a), (111-b), or (III) or General formula (II), and preferably has a dielectric loss tangent at 10 GHz of less than 0.002, a glass transition temperature of 250° C. or lower, and a weight average molecular weight of 1000 or more and 33000 or less. The weight average molecular weight may be less than 21000.

### (Storage Elastic Modulus)

Examples and preferred examples of the “storage elastic modulus” in the third embodiment and a method for adjusting the storage elastic modulus are the same as those described in “Storage Elastic Modulus” in the first embodiment.

In one embodiment, the substituted PPS resin contains a constituent unit represented by General formula (III-a), (III-b), or (III), and preferably has a dielectric loss tangent at 10 GHz of less than 0.002, a glass transition temperature of 250° C. or lower, a weight average molecular weight of 1000 or more and 33000 or less, and a storage elastic modulus at 260° C. of 1×10⁻⁵ Pa or more.

In one embodiment, the substituted PPS resin contains constituent units represented by General formula (III-a), (III-b), or (III) and General formula (I), and preferably has a dielectric loss tangent at 10 GHz of less than 0.002, a glass transition temperature of 250° C. or lower, a weight average molecular weight of 1000 or more and 33000 or less, and a storage elastic modulus at 260° C. of 1×10⁻⁵ Pa or more.

In one embodiment, the substituted PPS resin contains a terminal structure represented by General formula (III-a), (III-b), or (III) or General formula (II), and preferably has a dielectric loss tangent at 10 GHz of less than 0.002, a glass transition temperature of 250° C. or lower, a weight average molecular weight of 1000 or more and 33000 or less, and a storage elastic modulus at 260° C. of 1×10⁻⁵ Pa or more.

### [Resin Composition Containing Substituted PPS Resin]

The resin composition according to the third embodiment is a resin composition containing the substituted PPS resin according to the third embodiment.

The resin composition may be composed only of the substituted PPS resin or may contain an additional component.

For example, the resin composition may contain one or more components such as a curing catalyst, a flame retardant, a flame retardant synergist, a fiber reinforcing agent, a filler, a thermosetting additive, and/or a thermoplastic additive.

The content of the substituted PPS resin in the resin composition according to the present embodiment is not particularly limited, and can be appropriately determined by those skilled in the art in consideration of the properties of the substituted PPS resin and additional components according to the application of the resin composition. For example, the content may be 30 mass % or more, 40 mass % or more, 50 mass % or more, 60 mass % or more, 70 mass % or more, 80 mass % or more, 90 mass % or more, or 100 mass %.

When the content of the substituted PPS resin in the resin composition is 30 mass % or more, the dielectric loss tangent of the resin composition is likely to be less than 0.002, and/or the resin composition easily exhibits thermosetting property.

When the resin composition is used as a material for a wiring board, low dielectric loss tangent and/or thermosetting property is suitable.

### [Production Method]

The method for producing the substituted PPS resin in the third embodiment is the same as that described in “Production Method” in the first embodiment.

### [Product]

When the substituted PPS resin and/or the resin composition containing the substituted PPS resin according to the third embodiment has a low dielectric loss tangent, exhibits thermosetting property, and/or exhibits good reflow resistance, the substituted PPS resin and/or the resin composition can be widely used as a material for a wiring board or the like.

The wiring board includes all portions other than an electronic component such as a semiconductor in a printed wiring board (also referred to as printed circuit board). In general, the printed wiring board has a structure in which a semiconductor package including an electronic component such as a semiconductor mounted on a pedestal called substrate is mounted on a print circuit board (PCB), but the “board” “for a wiring board” also includes a substrate.

Although a product containing the substituted PPS resin and/or the resin composition is not limited, the product can be preferably used as an insulator component in a terminal of a mobile communication system when having a low dielectric loss tangent. When the thermosetting property of the material is required as a product or in its production process, the resin composition according to the present embodiment exhibiting thermosetting property can be preferably used. Further, when the reflow resistance of the material is required as a product or in its production process, a substituted PPS resin and/or a resin composition exhibiting good reflow resistance can be preferably used.

Examples of products containing the substituted PPS resin and/or resin composition according to the present embodiment include a varnish containing the substituted PPS resin and/or the resin composition and a solvent, an interlayer insulating material containing the substituted PPS resin and/or the resin composition, a prepreg containing the substituted PPS resin and/or the resin composition and a base material, a metal-clad laminate containing the substituted PPS resin and/or the resin composition and a metal foil, a substrate containing the substituted PPS resin and/or the resin composition, a wiring board containing the substituted PPS resin and/or the resin composition, and a printed wiring board containing the wiring board and an electronic component.

Applications of these products are not limited, and the products can be used for various applications requiring high-speed communication. For example, the products may be mounted on network devices/terminals, servers, AI processors, in-vehicle/aviation devices, home game machines, and the like.

Here, the above-mentioned products containing the substituted PPS resin and/or the resin composition each preferably have a dielectric loss tangent at 10 GHz of less than 0.002, and more preferably less than 0.001. When the dielectric loss tangent at 10 GHz of the product is less than 0.001, it may be less than 0.00095, less than 0.0009, or less than 0.00085.

When the dielectric loss tangent of the product is lower, the transmission loss is more easily suppressed.

In one embodiment, the printed wiring board including a wiring board (containing the substituted PPS resin and/or the resin composition) and an electronic component has a dielectric loss tangent at 10 GHz of preferably less than 0.002, and more preferably less than 0.001. When the dielectric loss tangent at 10 GHz of the printed wiring board is less than 0.001, it may be less than 0.00095, less than 0.0009, or less than 0.00085. When the dielectric loss tangent of the printed wiring board is lower, the transmission loss is more easily suppressed.

### (Varnish)

Examples and preferred examples of the “varnish” in the third embodiment are the same as those described in “Varnish” in the first embodiment.

### (Interlayer Insulating Material)

Examples and preferred examples of the “interlayer insulating material” in the third embodiment are the same as those described in “Interlayer Insulating Material” in the first embodiment.

### (Prepreg)

Examples and preferred examples of the “prepreg” in the third embodiment are the same as those described in “Prepreg” in the first embodiment.

### (Metal-Clad Laminate)

Examples and preferred examples of the “metal-clad laminate” in the third embodiment are the same as those described in “Metal-Clad Laminate” in the first embodiment.

### (Substrate)

Examples and preferred examples of the “substrate” in the third embodiment are the same as those described in “Substrate” in the first embodiment.

### (Wiring Board)

Examples and preferred examples of the “wiring board” in the third embodiment are the same as those described in “Wiring Board” in the first embodiment.

### (Printed Wiring Board)

Examples and preferred examples of the “printed wiring board” in the third embodiment are the same as those described in “Printed Wiring Board” in the first embodiment.

### EXAMPLES

The present disclosure will be described in more detail by way of Examples, but the interpretation of the present disclosure is not limited by the Examples.

### (Resin)

The resins used for evaluation are as follows. See Table 1.

### EXAMPLES

(1) 3,5-Dimethyl PPS resin (Mw: 3000)
(2) 3,5-Dimethyl PPS resin (Mw: 4400)
(3) 3,5-Dimethyl PPS resin (Mw: 6500)
(4) 3,5-Dimethyl PPS resin (Mw: 9000)
(5) 3,5-Dimethyl PPS resin (Mw: 19500)
(6) 3,5-Dimethyl PPS resin (Mw: 22500)
(7) 2,5-Dimethyl PPS resin (Mw: 1000)
(8) 3-Methyl PPS resin (Mw: 9200)
(9) 2-Isopropyl PPS resin (Mw: 5200)
(10) 3,5-Dimethyl PPS resin (Mw: 7600)
(11) 3,5-Dimethyl PPS resin (Mw: 4900; vinyl group-containing constituent unit: 1 mol % (random))
(12) 3,5-Dimethyl, 3-methyl PPS resin (Mw: 5200; vinyl group-containing constituent unit: 4 mol % (random))
(13) 3,5-Dimethyl PPS resin (Mw: 15000; vinyl group-containing constituent unit: 7 mol % (random))
(14) 3,5-Dimethyl PPS resin (Mw: 7300; vinyl group-containing 25 constituent unit: 18 mol % (random))
(15) 3,5-Dimethyl PPS resin (Mn: 2200; vinyl group-containing constituent unit: 13 mol % (terminal))
(16) 3,5-Dimethyl PPS resin (Mw: 15000; vinyl group-containing constituent unit: 4 mol % (terminal))
(17) 3,5-Dimethyl PPS resin (Mw: 14000; vinyl group-containing constituent unit: 4 mol % (terminal))
(18) 3,5-Dimethyl PPS resin (Mw: 16400; vinyl group-containing constituent unit: 3 mol % (terminal))
(19) 3,5-Dimethyl PPS resin (Mw: 24000; vinyl group-containing 35 constituent unit: 1 mol % (random))
(20) 3,5-Dimethyl PPS resin (Mw: 26000; vinyl group-containing constituent unit: 2 mol % (random))
(21) 3,5-Dimethyl PPS resin (Mw: 24000; vinyl group-containing constituent unit: 4 mol % (random))
(22) 3,5-Dimethyl PPS resin (Mw: 33000; vinyl group-containing constituent unit: 5 mol % (random))
(23) 3,5-Dimethyl PPS resin (Mw: 30000; vinyl group-containing constituent unit: 9 mol % (random))
(24) 3,5-Dimethyl PPS resin (Mw: 8400; vinyl group-containing constituent unit: 4 mol % (random))
(25) 2-Methyl-6-ethyl PPS resin (Mn: 3600) The resins of Examples 1 to 25 have an unsubstituted PPS constituent unit content of 0%.

### COMPARATIVE EXAMPLES

(1) Unsubstituted PPS resin (Mw: 1200; Mn: 800; unsubstituted PPS constituent unit content: 100%)
(2) Styrene-modified polyphenylene ether (PPE) resin (Mn: 1200) (Mitsubishi Gas Chemical Company, OPE-2St-1200) (vinyl group-containing constituent unit: 15 mol % (terminal))

### [Preparation]

### Resin Preparation 1: Example 4

56 ml of dichloromethane was introduced into a 100 ml three-necked flask in a nitrogen atmosphere. To the flask were added 3,3′-dimethyldiphenyl disulfide (11.5 g, 42 mmol), 2,3-dichloro-5,6-dicyano-parabenzoquinone (DDQ, 42 mmol), and trifluoromethanesulfonic acid (8.4 mmol). The mixture was stirred at room temperature for 6 hours for oxidative polymerization. The reaction liquid was added dropwise to hydrochloric acid-acidified methanol, and the resultant powder was recovered by filtration. Thereafter, the powder was washed with an aqueous potassium hydroxide solution (0.1 M) and pure water, and vacuum dried to produce a polymer. The polymer had an Mw of 9000 and an Mn of 4100.

### Resin Preparation 2: Examples 1 to 3, 5 to 10, and 25

Substituted PPS resins of Examples 1 to 3 and 5 to 10 were prepared in the same manner as in Resin Preparation 1 by a technique well known to those skilled in the art.

### Resin Preparation 3: Examples 11 to 14 and 19 to 24

### Synthesis of Vinyl-Substituted PPS Resin (Random)

Poly(2,6-dimethyl-1,4-phenylene sulfide) (10.0 g), N-bromosuccinimide (NBS) (9.75 mmol, 1.81 g), and AIBN (2.25 mmol, 0.37 g) were added to a 1000 ml eggplant-shaped flask, dissolved in chlorobenzene, and then reacted under reflux for 4 hours. After the reaction, the solution was cooled with ice water and the precipitated succinimide was filtered off with a glass filter. A filtrate was purified by precipitation with 5 wt % hydrochloric acid-acidified methanol, recovered using a glass filter, and vacuum dried to prepare bromo PPS (MXPPS) (yield: 85%, 9.05 g) in which some of protons of methyl groups were bromo-substituted. Subsequently, MXPPS (8.79 g) and triphenylphosphine (27.5 mmol) were added to a 2000 ml three-necked flask and dissolved in THF, followed by heating under reflux for 24 hours. Thereafter, the reaction solution was cooled to room temperature, 37 wt % aqueous formaldehyde solution (248 mmol) was added thereto, and the mixture was stirred for 10 minutes. As a result, the precipitate disappeared. Subsequently, potassium t-butoxide (33 mmol) was added and reacted for 1 hour. After completion of the reaction, the solution was concentrated to about ⅔, purified by precipitation with hydrochloric acid-acidified methanol, recovered by centrifugation, and vacuum dried to give a vinyl-substituted PPS resin (MVPPS) in which 7% of methyl groups were vinylated (yield: 93%, 7.89 g).

### Resin Preparation 4: Examples 15 to 17

### Synthesis of Vinyl-Substituted PPS Resin (Terminal)

### (First Method (Example 15))

2,3-Dichloro-5,6-dicyano-parabenzoquinone (DDQ, 5.25 mmol) was dispersed in dichloromethane (3.5 ml), trifluoroacetic acid (1.75 mmol) was added thereto, bis(2,6-dimethylphenyl)disulfide (2.63 mmol) was added thereto, and the mixture was stirred at room temperature for 1 hour. Thereafter, 4,4′-divinyldiphenyl disulfide (2.63 mmol) was further added to the mixture, and the mixture was stirred at room temperature for 15 hours, followed by purification by precipitation in hydrochloric acid-acidified methanol and filtration to recover a crude product. Thereafter, the crude product was dissolved in chloroform and reprecipitated with hydrochloric acid-acidified methanol to produce a vinyl-substituted PPS resin having a vinyl group in a terminal structure of the resin in the form of a white powder.

### (Second Method (Examples 16 and 17))

Bromo-terminated PPS was synthesized by adding poly(2,6-dimethyl-1,4-phenylene sulfide) to a solution of sulfonium cation (Br-DPS+) derived from Br-DPS (bis(4-bromophenyl)disulfide) in dichloromethane, followed by modification after polymerization. Specifically, in a 50 ml flask, Br-DPS (1.88 g, 5 mmol) was dissolved in dichloromethane (25 ml), TFA (trifluoroacetic acid) (0.83 ml, 12.5 mmol) and DDQ (1.14 g, 5 mmol) were added, and the mixture was stirred at room temperature. PMPS (0.68 g, 5 mmol as a repeating constituent unit) was further added, and the mixture was stirred at room temperature for 40 hours. This solution was precipitated in 5 vol % hydrochloric acid-containing methanol (1000 ml), and the solid was recovered by filtration, washed with methanol, an aqueous potassium hydroxide solution, and water, and dried in vacuo. The solid was reprecipitated with THF (tetrahydrofuran)/hexane (20 ml/800 ml), and the precipitate was recovered, washed with hexane, and dried in vacuo to prepare Br-PMPS (0.63 g, yield: 91%) (“VINYL-TERMINATED PPS1” in FIG. 1).

Bromo-terminated PPS and vinylmagnesium bromide were subjected to a Kumada-Tamao coupling reaction using Ni(dppp)Cl₂ ([1,3-bis(diphenylphosphino)propane]nickel(II) dichloride). Specifically, bromo-terminated PPS (96 mg, Br: 10 μmol) and Ni(dppp)Cl₂ (11 mg, 20 μmol) were added to a 30 ml flask and dissolved in THF (7.6 ml) in an argon atmosphere. A 1 M vinylmagnesium bromide solution (0.4 ml, 0.4 mmol) was further added in THF, and the mixture was stirred at room temperature for 24 hours. The solution was precipitated in 5 vol % hydrochloric acid-containing methanol (300 ml). The precipitate was recovered by filtration, washed with methanol and with water, and dried in vacuo to give a white powder (28 mg, yield: 29%, Mn=5.1×10³, Mw/Mn=2.3) (“VINYL-TERMINATED PPS2” in FIG. 1).

### Third Method: Example 18

2,3-Dichloro-5,6-dicyano-parabenzoquinone (DDQ, 26.3 mmol) was dispersed in dichloromethane (35 ml), trifluoroacetic acid was added thereto, bis(2,6-dimethylphenyl)disulfide (26.3 mmol) was then added thereto, the mixture was stirred at room temperature for 5 hours, and subjected to purification by precipitation in methanol to prepare a corresponding polymer (white solid). Tetrahydrofuran (76.5 ml) and 4-chloromethylstyrene (2.4 ml) were added to the polymer (5 g) for dissolution, and an aqueous sodium borohydride (0.645 g) solution (water: 8.5 ml) was further added, and the mixture was stirred at room temperature for 20 hours. The reaction liquid was subjected to purification by precipitation in methanol to produce a vinyl-substituted PPS resin having a vinyl group in the terminal structure of the resin.

### Evaluation of Vinyl-Substituted PPS Resin (Terminal) Synthesis by NMR

1H NMR spectra (500 MHz) were recorded with JEOL JNM-ECX500. Chemical shifts were calibrated using tetramethylsilane as an internal standard.

IR spectroscopy was performed with JASCO FT/IR-6100. Size exclusion chromatography (SEC) was performed with SHIMADZU LC-M20AD/CBM-20A using TOSOH TSKgel SuperHM-N column and SHIMADZU SPD-M20A UV detector (wavelength: 254 nm) (eluent: chloroform, flow rate: 0.3 ml min⁻¹, molecular weights were calibrated with polystyrene standards). Diffusion-ordered NMR-spectroscopy (DOSY) spectra (600 MHz) were recorded with Bruker AVANCE 600 NEO (pulse sequence: ledbpgp2s). Cyclic voltammetry (CV) was performed by BAS ALS 660D with a Pt wire, a Pt electrode (<p: 1.6 mm) and an Ag/AgCl electrode as a counter electrode, a working electrode, and a reference electrode, respectively. The potentials of the electrodes were each corrected by means of a ferrocene/ferrocenium redox couple (E½=0.45 V vs Ag/AgCl). Differential scanning calorimetry (DSC) was performed using a TA Instruments Q200 (scanning rate: 20° C. min⁻¹).

### Resin Preparation 5: Comparative Example 1

56 ml of dichloromethane was introduced into a 100 ml three-necked flask in a nitrogen atmosphere. To the flask were added diphenyl disulfide (42 mmol), 2,3-dichloro-5,6-dicyano-parabenzoquinone (DDQ, 42 mmol), and trifluoromethanesulfonic acid (42 mmol). The mixture was stirred at room temperature for 6 hours for oxidative polymerization. The reaction liquid was added dropwise to hydrochloric acid-acidified methanol, and the resultant powder was recovered by filtration. Thereafter, the powder was washed with an aqueous potassium hydroxide solution (0.1 M) and pure water, and vacuum dried to produce a polymer. The polymer had an Mw of 1200 and an Mn of 800.

[Measurement]

### (Measurement of Dielectric Loss Tangent and Dielectric Constant)

For measurement of the dielectric loss tangent and the dielectric constant, a film of each resin prepared with a thickness of from 50 to 250 μm was heated at from 200° C. to 250° C. for 120 minutes to prepare a sample piece of the resin for measurement.

The dielectric loss tangent and the dielectric constant were measured at 10 GHz, 40 GHz, or 80 GHz by a cavity resonator perturbation method under conditions of a standard environment (23±2° C.) and a relative humidity of from 45 to 55% by means of a vector network analyzer (N5290A) and a split cylinder resonator, both available from Keysight Technologies.

The dielectric loss tangent measured at 10 GHz was judged as follows.
0.002 or more: unacceptable
Less than 0.002: acceptable
Less than 0.0015: fair
Less than 0.001: good
Less than 0.0008: excellent

The dielectric loss tangent measured at 40 GHz was judged as follows.
0.003 or more: unacceptable
Less than 0.003: acceptable
Less than 0.002: fair
Less than 0.0015: good
Less than 0.0012: excellent 20 [0200]

The dielectric loss tangent measured at 80 GHz was judged as follows.
0.004 or more: unacceptable
Less than 0.004: acceptable
Less than 0.003: fair
Less than 0.0025: good
Less than 0.002: excellent

The dielectric constant measured at 10 GHz was judged as follows.
3.00 or more: unacceptable
Less than 3.00: acceptable
Less than 2.80: fair
Less than 2.60: good
Less than 2.40: excellent

### (Measurement of Glass Transition Temperature)

For each resin shown in Table 1, the glass transition temperature (Tg) was measured by differential scanning calorimetry (DSC) in accordance with JIS standard (JIS K 7121: Method for measuring transition temperature of plastics) under a temperature increase condition at 20° C./min from room temperature.

### (Weight Average Molecular Weight (Mw) and Number Average Molecular Weight (Mn))

For each resin (or resin composition) shown in Table 1, the weight average molecular weight (Mw) and the number average molecular weight (Mn) in terms of polystyrene were measured by gel permeation chromatography (GPC).

### (Storage Elastic Modulus)

The storage elastic modulus at 260° C. of the substituted PPS resin was measured at a frequency of 1 Hz and 260° C. using a dynamic viscoelasticity measuring apparatus (RSA-G2, available from TA Instruments). More specifically, the storage elastic modulus at 260° C. was measured at 260° C. using a dynamic viscoelasticity measuring apparatus (RSA-G2, available from TA Instruments) while the temperature was increased from room temperature at a rate of 5° C./min. A measurement sample (30 mm×3 mm) was cut out from a film having a uniform thickness in a range of from about 0.1 to 0.3 mm without causing a problem for measurement. The thickness of the sample was accurately determined, and the sample was used for measurement. Main measurement parameters involved in the measurement were as follows.
Measurement frequency: 10 Hz
Rate of temperature increase: 5° C./min
Sample measurement length: 15 mm
Strain: 0.05%

TABLE 1-1

| | Comparative Example | | Example | | | | | | |
|---|---|---|---|---|---|---|---|---|---|
| | 1 | 2 | 1 | 2 | 3 | 4 | 5 | 6 | 7 |
| Substitution position (R) in | — | — | 2.3 | 2.3 | 2.3 | 2.3 | 2.3 | 2.3 | 1.3 |
| General formula (I) | | | | | | | | | |
| Substituent | — | Methyl | Methyl | Methyl | Methyl | Methyl | Methyl | Methyl | Methyl |
| Amount (mol %) of unsaturated | 0 | 15 | 0 | 0 | 0 | 0 | 0 | 0 | 0 |
| bond (vinyl group)-containing | | | | | | | | | |
| constituent unit introduced | | | | | | | | | |
| Unsaturated bond (vinyl group) | — | Terminal | — | — | — | — | — | — | — |
| introduction position | | | | | | | | | |
| Number average molecular | 800 | 1200 | 1800 | 1900 | 3400 | 4100 | 9500 | 11100 | 650 |
| weight (Mn) | | | | | | | | | |
| Weight average molecular | 1200 | — | 3000 | 4400 | 6500 | 9000 | 19500 | 22500 | 1000 |
| weight (Mw) | | | | | | | | | |
| Tg | | 179 | 109 | 115 | 153 | 155 | 158 | 172 | 194 |
| Dielectric constant (Dk) | Acceptable | Fair | Good | Good | Good | Good | Good | Excellent | Acceptable |
| Dielectric loss tangent (Df) | Unacceptable | Unacceptable | Good | Excellent | Good | Good | Good | Good | Excellent |
| @10 GHz | | | | | | | | | |
| Dielectric loss tangent (Df) | Unacceptable | Acceptable | Fair | Excellent | Good | Good | Good | Good | Excellent |
| @40 GHz | | | | | | | | | |
| Storage elastic modulus | 1 | 2 | 1 | 1 | 1 | 1 | 1 | 1 | 1 |

TABLE 1-2

| | Example | | | | | | | | |
|---|---|---|---|---|---|---|---|---|---|
| | 8 | 9 | 10 | 11 | 12 | 13 | 14 | 15 | 16 |
| Substitution position (R) in | 2 | 1 | 2.3 | 2.3 | 2.3 | 2.3 | 2.3 | 2.3 | 2.3 |
| General formula (I) | | | | | | | | | |
| Substituent | Methyl | i- | Methyl | Methyl | Methyl | Methyl | Methyl | Methyl | Methyl |
| | | Propyl | | | | | | | |
| Amount (mol %) of unsaturated | 0 | 0 | 0 | 1 | 4 | 7 | 18 | 13 | 4 |
| bond (vinyl group)-containing | | | | | | | | | |
| constituent unit introduced | | | | | | | | | |
| Unsaturated bond (vinyl group) | — | — | — | Random | Random | Random | Random | Terminal | Terminal |
| introduction position | | | | | | | | | |
| Number average molecular | 4100 | 2000 | 3100 | 3200 | 3100 | 4200 | 3300 | 2200 | 7400 |
| weight (Mn) | | | | | | | | | |
| Weight average molecular | 9200 | 5200 | 7600 | 4900 | 5200 | 15000 | 7300 | — | 15000 |
| weight (Mw) | | | | | | | | | |
| Tg | 90 | 70 | 104 | 154 | 166 | 196 | 195 | | 183 |
| Dielectric constant (Dk) | Fair | Fair | Fair | Fair | Fair | Good | Fair | Fair | Fair |
| Dielectric loss tangent (Df) | Excellent | Good | Excellent | Good | Acceptable | Fair | Acceptable | Good | Fair |
| @10 GHz | | | | | | | | | |
| Dielectric loss tangent (Df) | Excellent | Fair | Excellent | Good | Acceptable | Fair | Acceptable | Good | Fair |
| @40 GHz | | | | | | | | | |
| Storage elastic modulus | 1 | 1 | 1 | 2 | 2 | 2 | 2 | 2 | 2 |

TABLE 1-3

| | Example | | | | | | | | |
|---|---|---|---|---|---|---|---|---|---|
| | 17 | 18 | 19 | 20 | 21 | 22 | 23 | 24 | 25 |
| Substitution position (R) in | 2.3 | 2.3 | 2.3 | 2.3 | 2.3 | 2.3 | 2.3 | 2 | 1.4 |
| General formula (I) | | | | | | | | | |
| Substituent | Methyl | Methyl | Methyl | Methyl | Methyl | Methyl | Methyl | Methyl | Methyl, |
| | | | | | | | | | Ethyl |
| Amount (mol %) of unsaturated | 4 | 3 | 1 | 2 | 4 | 5 | 9 | 4 | 0 |
| bond (vinyl group)-containing | | | | | | | | | |
| constituent unit introduced | | | | | | | | | |
| Unsaturated bond (vinyl group) | Terminal | Terminal | Random | Random | Random | Random | Random | Random | — |
| introduction position | | | | | | | | | |
| Number average molecular | 6800 | 5200 | 6200 | 7300 | 7300 | 7600 | 8200 | 3000 | 1800 |
| weight (Mn) | | | | | | | | | |
| Weight average molecular | 14000 | 16400 | 24000 | 26000 | 24000 | 33000 | 30000 | 8400 | 3600 |
| weight (Mw) | | | | | | | | | |
| Tg | 180 | 175 | 185 | 192 | 185 | 185 | 190 | 108 | — |
| Dielectric constant (Dk) | Fair | Fair | Fair | Fair | Fair | Fair | Fair | Acceptable | Fair |
| Dielectric loss tangent (Df) | Fair | Good | Good | Good | Fai | Fair | Fair | Fair | Acceptable |
| @10 GHz | | | | | | | | | |
| Dielectric loss tangent (Df) | Fair | Good | Good | Good | Fair | Fair | Fair | Fair | Acceptable |
| @40 GHz | | | | | | | | | |
| Storage elastic modulus | 2 | 2 | 2 | 2 | 2 | 2 | 2 | 2 | 1 |

Dielectric loss tangent (Df) @10 GHz: 0.002 or more: unacceptable; less than 0.002: acceptable; less than 0.0015: fair; less than 0.001: good; less than 0.0008: excellent.

Dielectric loss tangent (Df) @40 GHz: 0.003 or more: unacceptable; less than 0.003: acceptable; less than 0.002: fair; less than 0.0015: good; less than 0.0012: excellent.

Dielectric constant (Dk) @10 GHz: 3.00 or more: unacceptable; less than 3.00: acceptable; less than 2.80: fair; less than 2.60: good; less than 2.40: excellent.

Storage elastic modulus (260° C.): less than 1×10⁵: “1”; 1×10⁵ or more: “2”

As shown in Table 1, the substituted PPS resins of Examples 1 to 25 were “acceptable” (less than 0.002) to “excellent” (less than 0.0008) in terms of dielectric loss tangent at 10 GHz.

In contrast, the unsubstituted PPS resin of Comparative Example 1 and the PPE resin of Comparative Example 2 were “unacceptable” (0.002 or more) in terms of dielectric loss tangent at 10 GHz.

Furthermore, in terms of dielectric loss tangent at 40 GHz, the substituted PPS resins of Examples 1 to 25 were “acceptable” (less than 0.003) to “excellent” (less than 0.0012), whereas the unsubstituted PPS resin of Comparative Example 1 and the PPE resin of Comparative Example 2 were “unacceptable” (0.003 or more) and “acceptable” (less than 0.003), respectively.

In terms of dielectric loss tangent at 80 GHz, the substituted PPS resin of Example 5 was “good” (less than 0.0025), whereas the unsubstituted PPS resin of Comparative Example 1 and the PPE resin of Comparative Example 2 were “unacceptable” (0.004 or more) and “acceptable” (less than 0.004), respectively.

In addition, as shown in Table 1, the substituted PPS resins of Examples 1 to 25 were “acceptable” (less than 3.00) to “excellent” (less than 2.40) in terms of dielectric constant at 10 GHz, whereas the unsubstituted PPS resin of Comparative Example 1 and the PPE resin of Comparative Example 2 were “acceptable” (less than 3.00) and “fair” (less than 2.80) in terms of dielectric constant at 10 GHz, respectively.

For the substituted PPS resins of Examples 15 to 18, synthesis of a vinyl-substituted PPS resin (terminal) was evaluated by the above-described NMR method. As illustrated in FIG. 2, terminal vinylation was confirmed from an upfield shift of a signal of a terminal aromatic proton and the presence of a signal of a terminal vinyl group.

From the above results, it was confirmed that the substituted PPS resins described in the first to third embodiments had a low dielectric loss tangent.

Furthermore, as shown in Table 1, the substituted PPS resins of Examples 11 to 24 had a storage elastic modulus of “2” (1×10⁵ or more), whereas the substituted PPS resins of Examples 1 to 10 and 25 had a storage elastic modulus of “1” (less than 1×10⁵), the unsubstituted PPS resin of Comparative Example 1 had a storage elastic modulus of “1”, and the PPE resin of Comparative Example 2 had a storage elastic modulus of “^{2”}.

The storage elastic modulus of the substituted PPS resin of Example 20 was 8.5×10⁵ Pa, and the storage elastic modulus of the substituted PPS resin of Example 21 was 1.7×10⁶ Pa.

The results demonstrated that the substituted PPS resins described in the first to third embodiments into which an unsaturated bond-containing constituent unit had been introduced had a storage elastic modulus of 1×10⁵ or more, and had good reflow resistance.

### INDUSTRIAL APPLICABILITY

The substituted polyphenylene sulfide resin of the present disclosure has a low dielectric loss tangent, and thus can be suitably used as a material for a printed wiring board or the like, and has industrial applicability.

1-7. (canceled)

8. A substituted polyphenylene sulfide resin comprising a constituent unit represented by General formula (I): 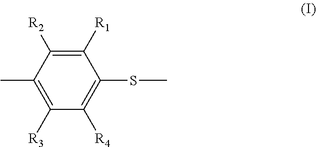
[wherein R₁, R₂, R₃, and R₄ are each independently H, an alkyl group, an alkoxy group, or an alkenyl group-containing organic group, and one or more of R₁, R₂, R₃, and R₄ are an alkyl group or an alkoxy group], wherein
the substituted polyphenylene sulfide resin has a dielectric loss tangent at 10 GHz of less than 0.002.

9. The substituted polyphenylene sulfide resin according to claim 8, wherein the substituted polyphenylene sulfide resin comprises a constituent unit represented by General formula (II): 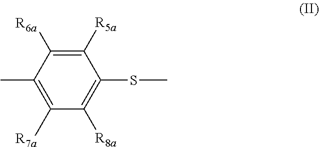
[wherein R₅ₐ, R₆ₐ, R₇ₐ, and R₈ₐ are each independently H, an alkyl group, an alkoxy group, or an alkenyl group-containing organic group, and one or more of R₅ₐ, R₆ₐ, R₇ₐ, and R₈ₐ are an alkenyl group-containing organic group]; and/or a terminal structure represented by General formula (Ill-a): 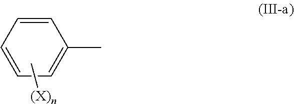
[wherein Xs are each independently H, an alkyl group, an alkoxy group, or an alkenyl group-containing organic group, one or more of Xs are an alkenyl group-containing organic group, and n is an integer of from 1 to 5].

10. The substituted polyphenylene sulfide resin according to claim 8, wherein the substituted polyphenylene sulfide resin has a glass transition temperature of 250° C. or lower.

11. The substituted polyphenylene sulfide resin according to claim 8, wherein a content of the constituent unit containing an alkyl group and/or an alkoxy group is 30 mol % or more.

12. The substituted polyphenylene sulfide resin according to claim 11, wherein a content of the constituent unit containing an alkenyl group-containing organic group is 20 mol % or less.

13. A resin composition comprising the substituted polyphenylene sulfide resin described in claim 8.

14. A substituted polyphenylene sulfide resin comprising a terminal structure represented by General formula (Ill-a): 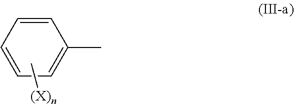
[wherein Xs are each independently H, an alkyl group, an alkoxy group, or an alkenyl group-containing organic group, one or more of Xs are an alkenyl group-containing organic group, and n is an integer of from 1 to 5].

15. The substituted polyphenylene sulfide resin according to claim 14, wherein the substituted polyphenylene sulfide resin comprises a constituent unit represented by General formula (I): 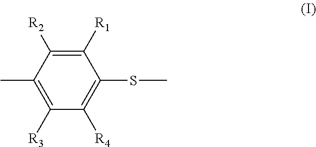
[wherein R₁, R₂, R₃, and R₄ are each independently H, an alkyl group, an alkoxy group, or an alkenyl group-containing organic group, and one or more of R₁, R₂, R₃, and R₄ are an alkyl group or an alkoxy group].

16. The substituted polyphenylene sulfide resin according to claim 15, wherein the substituted polyphenylene sulfide resin has a dielectric loss tangent at 10 GHz of less than 0.002.

17. The substituted polyphenylene sulfide resin according to claim 14, wherein the substituted polyphenylene sulfide resin comprises a constituent unit represented by General formula (II): 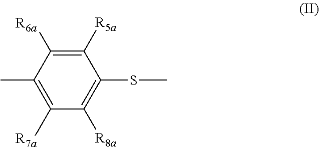
[wherein R₅ₐ, R₆ₐ, R₇ₐ, and R₈ₐ are each independently H, an alkyl group, an alkoxy group, or an alkenyl group-containing organic group, and one or more of R₅ₐ, R₆ₐ, R₇ₐ, and R₈ₐ are an alkenyl group-containing organic group].

18. The substituted polyphenylene sulfide resin according to claim 14, wherein the substituted polyphenylene sulfide resin has a glass transition temperature of 250° C. or lower.

19. The substituted polyphenylene sulfide resin according to claim 14, wherein a content of the constituent unit containing an alkyl group and/or an alkoxy group is 30 mol % or more.

20. The substituted polyphenylene sulfide resin according to claim 19, wherein a content of the constituent unit containing an alkenyl group-containing organic group is 20 mol % or less.

21. A resin composition comprising the substituted polyphenylene sulfide resin described in claim 14.

22. A varnish comprising the resin described in claim 8, and a solvent.

23-29. (canceled)

30. A varnish comprising the resin described in claim 14, and a solvent.

31. An interlayer insulating material comprising the resin described in claim 8.

32. An interlayer insulating material comprising the resin described in claim 14.

33. A prepreg comprising the resin described in claim 8 and a base material.

34. A prepreg comprising the resin described in claim 14, and a base material.

35. A metal-clad laminate comprising the resin described in claim 8 and a metal foil.

36. A metal-clad laminate comprising the resin described in claim 14, and a metal foil.

37. A substrate comprising the resin described in claim 8.

38. A substrate comprising the resin described in claim 14.

39. A wiring board comprising the resin described in claim 8.

40. A wiring board comprising the resin described in claim 14.

41. A printed wiring board comprising the wiring board described in claim 39 and an electronic component.

42. A printed wiring board comprising the wiring board described in claim 40 and an electronic component.

43. The printed wiring board according to claim 41, wherein the printed wiring board has a dielectric loss tangent at 10 GHz is less than 0.002.

44. The printed wiring board according to claim 42, wherein the printed wiring board has a dielectric loss tangent at 10 GHz is less than 0.002.
